(19) United States
(12) Patent Application Publication
(10) Pub. No.: US 2023/0354664 A1
(43) Pub. Date: Nov. 2, 2023

(54) DISPLAY DEVICE

(71) Applicant: Samsung Display Co., LTD., Yongin-si (KR)

(72) Inventors: Shin Hyuk YANG, Yongin-si (KR); Jee Hoon KIM, Yongin-si (KR); Dong Han KANG, Yongin-si (KR)

(73) Assignee: Samsung Display Co., LTD., Yongin-si (KR)

(21) Appl. No.: 18/118,308

(22) Filed: Mar. 7, 2023

(30) Foreign Application Priority Data
Apr. 27, 2022 (KR) 10-2022-0052225

(51) Int. Cl. H10K 59/131; G09G 3/3233

(52) U.S. Cl. CPC H10K 59/1315; G09G 3/3233; G09G 2300/0842; G09G 2300/0819

(57) ABSTRACT

A display device includes a substrate, an emission layer disposed on the substrate, and a plurality of signal lines disposed on the substrate, electrically connected to the emission layer, and including a first signal line. The first signal line includes a first layer including a refractory metal, a second layer disposed on the first layer and including a low-resistance metal, a third layer disposed on the second layer and including a first metal oxide, and a fourth layer disposed on the third layer and including a second metal oxide, and the first metal oxide of the third layer includes the low-resistance metal of the second layer.

### CROSS-REFERENCE TO RELATED APPLICATION(S)

This application claims priority to and benefits of Korean Patent Application No. 10-2022-0052225 under 35 U.S.C. § 119, filed on Apr. 27, 2022, in the Korean Intellectual Property Office, the entire contents of which are incorporated herein by reference.

### BACKGROUND

### 1. Technical Field

Embodiments relate to a display device.

### 2. Description of the Related Art

A display device includes a liquid crystal display (LCD), a plasma display panel (PDP), a light emitting diode device (OLED device), a field emission display (FED), and an electrophoretic display device.

The light emitting diode device may not require a separate light source such as a backlight, thereby reducing the thickness and weight of the display device. The light emitting diode device has high quality characteristics such as low power consumption, high luminance, and high response speed.

The light emitting diode device may include a display area corresponding to a screen for displaying an image, and pixels may be disposed in the display area. The pixels may be implemented by light emitting diodes. The light emitting diode may include two electrodes and an emission layer disposed therebetween. One of the two electrodes may be a pixel electrode of each pixel, and the other electrode may be a common electrode of a plurality of pixels.

Signals are transmitted through signal lines connected to the pixel electrode and the common electrode, and as the size of the display device increases, a signal delay may occur according to a position of the display device.

A plurality of thin film layers including signal lines connected to the pixel electrode and the common electrode are formed on a substrate. However, in case that a taper angle of an edge portion of the thin film layer disposed below increases and the roughness increases, problems such as disconnection or lifting of an insulating film or an upper thin film layer formed thereon may occur.

The above information disclosed in this Background section is only for enhancement of understanding of the background of the described technology.

### SUMMARY

Embodiments provide a display device capable of preventing or minimizing a signal delay of signals provided to signal lines of the display device and capable of reducing or minimizing a taper angle and roughness of the signal lines.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include a substrate, an emission layer disposed on the substrate, and a plurality of signal lines disposed on the substrate, electrically connected to the emission layer, and including a first signal line, wherein the first signal line may include a first layer including a refractory metal, a second layer disposed on the first layer and including a low-resistance metal, a third layer disposed on the second layer and including a first metal oxide, and a fourth layer disposed on the third layer and including a second metal oxide, and the first metal oxide of the third layer may include the low-resistance metal of the second layer.

The first layer may include titanium, the second layer may include copper, and the third layer may include copper oxide.

The fourth layer may include transparent conductive oxide (TCO).

The fourth layer may include at least one of indium tin oxide (ITO), zinc indium tin oxide (ZITO), indium zinc oxide (IZO), and aluminum zinc oxide (AZO).

A thickness of the fourth layer may be about 50 angstroms to about 1000 angstroms.

A thickness of the second layer may be greater than a thickness of the first layer and a thickness of the third layer.

The third layer and the fourth layer of the first signal line may be removed from a first portion of the first signal line to expose the second layer of the first signal line.

A part of the fourth layer may be removed from the first portion of the first signal line.

The display device may further include a first insulating layer disposed on the first signal line and including a contact hole, wherein the first portion of the first signal line may overlap the contact hole.

The display device may further include a transistor electrically connected to the emission layer and including a semiconductor layer, wherein the first signal line may be disposed between the substrate and the semiconductor layer.

In an embodiment, a display device may include a substrate, a first conductive layer disposed on the substrate, a first insulating layer disposed on the first conductive layer, a semiconductor layer disposed on the first insulating layer, a second insulating layer disposed on the semiconductor layer, a second conductive layer disposed on the second insulating layer, a third insulating layer disposed on the second conductive layer, a third conductive layer disposed on the third insulating layer, a fourth insulating layer disposed on the third conductive layer, and an emission layer disposed on the fourth insulating layer and electrically connected to the third conductive layer, wherein each of the first conductive layer and the second conductive layer may include a first layer including a refractory metal, a second layer disposed on the first layer and including a low-resistance metal, a third layer disposed on the second layer and including a first metal oxide, and a fourth layer disposed on the third layer and including a second metal oxide, wherein the third layer and the fourth layer of the first conductive layer may be removed from a first portion of the first conductive layer and the third layer and the fourth layer of the second conductive layer may be removed from a second portion of the second conductive layer.

The first insulating layer, the second insulating layer and the third insulating layer may include a first contact hole overlapping the first portion of the first conductive layer, the third insulating layer may include a second contact hole overlapping the second portion of the second conductive layer, and the third conductive layer may be electrically connected to the first conductive layer and the second conductive layer through the first contact hole and the second contact hole.

The first layer may include titanium, the second layer may include copper, the third layer may include copper oxide, and the fourth layer may include transparent conductive oxide (TCO).

The third conductive layer may include a first layer including a refractory metal, a second layer disposed on the first layer and including a low-resistance metal, a third layer disposed on the second layer and including a refractory metal, and a fourth layer disposed on the third layer and including a second metal oxide, the fourth insulating layer may include a third contact hole overlapping a third portion of the third conductive layer, the emission layer may be electrically connected to the third conductive layer through the third contact hole, and the fourth layer may not be removed from the third portion of the third conductive layer.

The first layer of the third conductive layer may include titanium, the second layer of the third conductive layer may include copper, the third layer of the third conductive layer may include titanium, and the fourth layer of the third conductive layer may include transparent conductive oxide (TCO).

According to the embodiments, a signal delay of signals provided to signal lines of the display device may be prevented or minimized, and a taper angle and roughness of the signal lines may be reduced or minimized.

However, the effects of the embodiments are not limited to the above-described effects, and it is apparent that the effects can be variously expanded without departing from the spirit and scope of this disclosure.

### BRIEF DESCRIPTION OF THE DRAWINGS

FIG. 1 is a schematic plan view of a light emitting diode device according to an embodiment.

FIG. 2 is a schematic diagram of an equivalent circuit of a pixel of the light emitting diode device according to an embodiment.

FIG. 3 is a schematic plan view of a pixel area of the light emitting diode device according to an embodiment.

FIG. 4 is a schematic cross-sectional view taken along line A-A′ of FIG. 3.

FIG. 5 is a schematic cross-sectional view taken along line B-B′ of FIG. 3.

FIG. 6 is a schematic enlarged view illustrating a part of FIG. 5.

FIG. 7 is a schematic enlarged view illustrating a part of FIG. 5.

FIGS. 8, 11, 14, 17, 20 and 23 are schematic plan views illustrating the light emitting diode device illustrated in FIG. 3 according to a manufacturing sequence.

FIGS. 9 and 10 are schematic cross-sectional views illustrating a part of FIG. 8.

FIGS. 12 and 13 are schematic cross-sectional views illustrating a part of FIG. 11.

FIGS. 15 and 16 are schematic cross-sectional views illustrating a part of FIG. 14.

FIGS. 18 and 19 are schematic cross-sectional views illustrating a part of FIG. 17.

FIGS. 21 and 22 are schematic cross-sectional views illustrating a part of FIG. 20.

FIGS. 24 and 25 are schematic cross-sectional views illustrating a part of FIG. 23.

FIG. 26 is a schematic cross-sectional view of a display device according to an embodiment.

FIGS. 27 and 28 are schematic enlarged views illustrating a part of FIG. 26.

FIG. 29 is a schematic cross-sectional view of a display area in the light emitting diode device according to an embodiment.

FIGS. 30, 31 and 32 are electron micrographs showing results of one Experimental Example.

FIG. 33 is an electron micrograph showing results of another Experimental Example.

### DETAILED DESCRIPTION OF THE EMBODIMENTS

The embodiment will be described more fully hereinafter with reference to the accompanying drawings, in which various embodiments are shown. The embodiments may be implemented in various different forms and is not limited to embodiments described herein.

A part irrelevant to the description will be omitted to clearly describe the embodiments, and like or similar components will be designated by like reference numerals throughout the description.

Also, it should be understood that the appended drawings are intended only to help understand embodiments disclosed in the descriptions and do not limit the technical principles and scope of this disclosure; rather, it should be understood that the appended drawings include all of the modifications, equivalents or substitutes described by the technical principles and belonging to the technical scope of the disclosure.

Each configuration illustrated in the drawings is arbitrarily shown for understanding and ease of description, but embodiments are not limited thereto. In the drawings, the thickness of layers, films, panels, regions, etc., are exaggerated for clarity. In the drawings, for convenience of description, thicknesses of a part and an area are exaggeratedly illustrated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, “above” or “on” a reference portion is located above or below the reference portion and does not necessarily mean to be located “above” or “on” an opposite direction of gravity.

Unless explicitly described to the contrary, the word “comprise”, and variations such as “comprises” or “comprising”, will be understood to imply the inclusion of stated elements but not the exclusion of any other elements.

Throughout the description, when referring to “on a plane”, it is meant when a target part is viewed from the top, and when referring to “on a cross-section”, it is meant when a target part is viewed from the side when the cross-section of the target part is vertically cut.

Throughout the description, when referring to “connected”, it is not meant that two or more components are directly connected to each other, but it may be meant that two or more components are indirectly connected through other components, not only physically connected, but also electrically connected, or integrated although referred to by different names depending on their locations or functions.

In the drawings, symbols “x”, “y” and “z” are used to indicate directions, wherein “x” is a first direction, “y” is a second direction perpendicular to the first direction, and “z” is a third direction perpendicular to the first direction and the second direction. The first direction x, the second direction y, and the third direction z may correspond to a horizontal direction, a vertical direction, and a thickness direction of the display device, respectively.

Hereinafter, various embodiments and modifications will be described in detail with reference to the accompanying drawings.

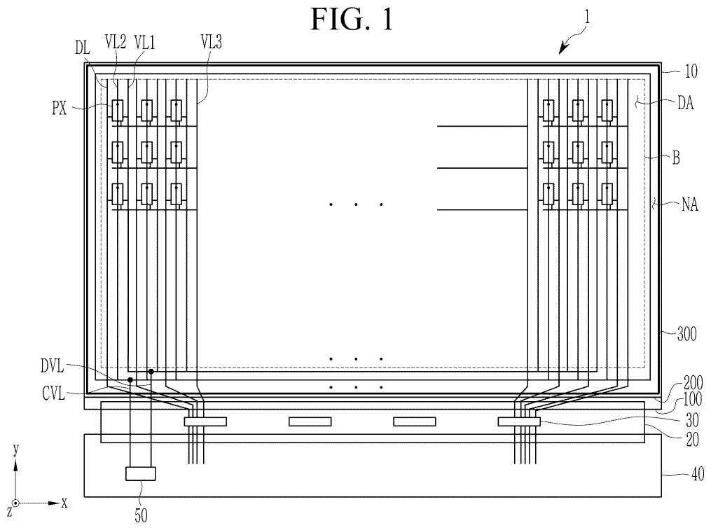

FIG. 1 is a schematic plan view of a light emitting diode device according to an embodiment.

Referring to FIG. 1, a light emitting diode device 1 (hereinafter, referred to as a “display device”) may include a display panel 10, a flexible printed circuit film 20, a driving integrated circuit chip 30, a printed circuit board 40, a power module 50, and the like.

The display panel 10 may include a display area DA, which functions as a screen for displaying an image and a non-display area NA disposed with circuits and/or lines for generating and/or transmitting various signals applied to the display area DA. The non-display area NA may be adjacent to the display area DA and surround the display area DA. In FIG. 1, an inner area and an outer area of a boundary line B may be the display area DA and the non-display area NA, respectively.

The display panel 10 may include a display unit 100 and a color conversion unit 200. The display unit 100 and the color conversion unit 200 may be bonded to each other by a sealing material 300 disposed between the display unit 100 and the color conversion unit 200 to surround an edge portion of the display panel 10. The color conversion unit 200 may overlap (e.g., entirely overlap) the display unit 100. In another example, the display unit 100 may include an area which is not covered by the color conversion unit 200 for connection or bonding of the flexible printed circuit film 20. The display unit 100 may include a pad unit for connecting or bonding of the flexible printed circuit film 20, and the color conversion unit 200 may be shorter than the display unit 100 in an area where the pad unit is disposed, for example, at a lower end portion of the display panel 10 so that the pad unit may be exposed to the outside. The display unit 100 and the color conversion unit 200 may include areas corresponding to the display area DA and the non-display area NA of the display panel 10, respectively.

Pixels PX may be disposed in a matrix in the display area DA of the display panel 10. In the display area DA, a data line DL transmitting a data voltage V_{DATA}, a driving voltage line VL1 transmitting a driving voltage EL_{VDD}, a common voltage line VL2 transmitting a common voltage EL_{VSS}, and an initialization voltage line VL3 transmitting an initialization voltage V_{INT} may be disposed. The driving voltage line VL1, the common voltage line VL2 and the initialization voltage line VL3 may extend in a second direction y. The driving voltage line VL1, the common voltage line VL2 and/or the initialization voltage line VL3 may be connected (e.g., electrically connected) to an auxiliary voltage line in extending in a first direction x. Each pixel PX may receive the data voltage V_{DATA}, the driving voltage EL_{VDD}, the common voltage EL_{VSS} and the initialization voltage V_{INT} from these voltage lines DL, VL1, VL2, and VL3. The driving voltage EL_{VDD} and the common voltage EL_{VSS} may be power voltages applied to each pixel PX and the driving voltage line VL1 and the common voltage line VL2 transmitting these power voltages may be referred to as power voltage lines. The driving voltage EL_{VDD} may be higher than the common voltage EL_{VSS}. The driving voltage EL_{VDD} may be referred to as a first power supply voltage or a high potential power supply voltage. The common voltage EL_{VSS} may be referred to as a second power supply voltage or a low potential power supply voltage.

In the non-display area NA of the display panel 10, gate drivers may be disposed on sides (e.g., opposite sides) of the display area DA. The gate driver may be formed in the non-display area NA. The pixels PX may receive a gate signal (also referred to as a scan signal) generated by the gate driver to receive the data voltage V_{DATA} at a certain timing.

In the non-display area NA of the display panel 10, a driving voltage transfer line DVL connected (e.g., electrically connected) to the driving voltage lines VL1 and a common voltage transfer line CVL connected (e.g., electrically connected) to the common voltage lines VL2 may be disposed. The driving voltage transfer line DVL and the common voltage transfer line CVL may include portions extending in the second direction y and portions extending in the first direction x, respectively. The common voltage transfer line CVL may be disposed to surround the display area DA. The common voltage lines VL2 may be connected (e.g., electrically connected) to the common voltage transfer line CVL at the lower and upper sides of the display area DA, thereby uniformly supplying the common voltage EL_{VSS} over the entire display area DA.

An end portion of the flexible printed circuit film 20 may be connected or bonded to the display unit 100 of the display panel 10, and another end portion thereof may be connected or bonded to the printed circuit board 40. The driving integrated circuit chip 30 including a data driver for applying the data voltage V_{DATA} to the data line DL may be disposed on the flexible printed circuit film 20.

The power module 50 generating a power supply voltage such as the driving voltage EL_{VDD} and a common voltage EL_{VSS} may be disposed on the printed circuit board 40. The power module 50 may be formed as an integrated circuit chip. A signal controller for controlling the data driver and the gate driver may be disposed on the printed circuit board 40.

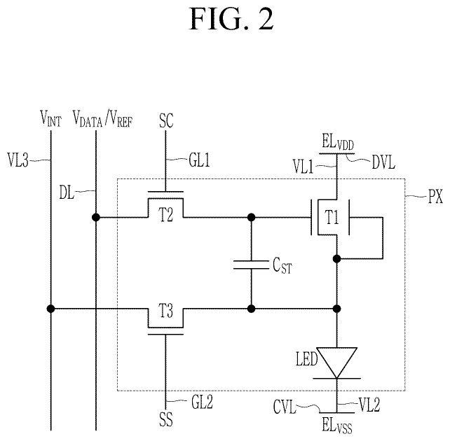

FIG. 2 is a schematic diagram of an equivalent circuit of a pixel of the light emitting diode device according to an embodiment.

Referring to FIG. 2, one pixel PX may include first to third transistors T1, T2, and T3, a storage capacitor C_{ST}, and a light emitting diode LED. The light emitting diode LED may be an organic or inorganic light emitting diode. The first to third transistors T1, T2, and T3 may be N-type transistors, and at least some thereof may be P-type transistors.

A gate electrode of the first transistor T1 may be connected (e.g., electrically connected) to a first electrode of the storage capacitor C_{ST}. The first electrode of the first transistor T1 may be connected (e.g., electrically connected) to the driving voltage line VL1 that transmits the driving voltage EL_{VDD}, and a second electrode of the first transistor T1 may be connected (e.g., electrically connected) to an anode of the light emitting diode LED and a second electrode of the storage capacitor C_{ST}. The first transistor T1 may receive the data voltage V_{DATA} according to a switching operation of the second transistor T2 and may supply a driving current to the light emitting diode LED according to the voltage stored in the storage capacitor C_{ST}.

A gate electrode of the second transistor T2 may be connected (e.g., electrically connected) to a first gate line GL1 through which a first scan signal SC is transmitted. A first electrode of the second transistor T2 may be connected (e.g., electrically connected) to a data line DL through which the data voltage V_{DATA} or a reference voltage V_{REF} may be transmitted. A second electrode of the second transistor T2 may be connected (e.g., electrically connected) to a first electrode of the storage capacitor C_{ST} and the gate electrode of the first transistor T1. The second transistor T2 may be turned on according to the first scan signal SC to transmit the reference voltage V_{REF} or the data voltage V_{DATA} to the gate electrode of the first transistor T1.

A gate electrode of the third transistor T3 may be connected (e.g., electrically connected) to the second gate line GL2 through which a second scan signal SS is transmitted. A first electrode of the third transistor T3 may be connected (e.g., electrically connected) to the initialization voltage line VL3 transmitting the initialization voltage V_{INT}. A second electrode of the third transistor T3 may be connected (e.g., electrically connected) to the second electrode of the storage capacitor C_{ST}, the second electrode of the first transistor T1, and the anode of the light emitting diode LED. In case that the third transistor T3 is turned on according to the second scan signal SS, the initialization voltage V_{INT} may be transmitted to the anode of the light emitting diode LED to initialize the voltage of the anode of the light emitting diode LED.

The first electrode of the storage capacitor C_{ST} may be connected (e.g., electrically connected) to the gate electrode of the first transistor T1. The second electrode of the storage capacitor C_{ST} may be connected (e.g., electrically connected) to the second electrode of the third transistor T3 and the anode of the light emitting diode LED. A cathode of the light emitting diode LED may be connected (e.g., electrically connected) to the common voltage line VL2 transmitting the common voltage EL_{VSS}. Each light emitting diode LED may include one pixel PX, and the anode and the cathode of the light emitting diode LED may be referred to as a pixel electrode and a common electrode, respectively.

The light emitting diode LED may emit light having a luminance (e.g., grayscale level) according to the driving current generated by the first transistor T1.

An example of the operation of the circuit illustrated in FIG. 2, e.g., an operation during one frame, will be described as an example of a case where all of the transistors T1 to T3 are N-type transistors.

In case that one frame starts, and the first scan signal SC and the second scan signal SS are at low levels in an initialization period, the common voltage EL_{VSS} may be applied as a high level voltage. Thus, a current from flowing through the light emitting diode LED may be prevented or blocked. Accordingly, the light emitting diode LED may not emit light. For example, the initialization voltage V_{INT} may be applied through the initialization voltage line VL3 to initialize the initialization voltage line VL3. The high-level first scan signal SC and the high-level second scan signal SS may be supplied to turn on the second transistor T2 and the third transistor T3. The reference voltage V_{REF} from the data line DL may be supplied to the gate electrode of the first transistor T1 and the first electrode of the storage capacitor C_{ST} through the turned-on second transistor T2. The initialization voltage V_{INT} may be supplied to the second electrode of the first transistor T1 and the anode of the light emitting diode LED through the turned-on third transistor T3. Accordingly, during the initialization period, the anode of the light emitting diode LED may be initialized to the initialization voltage V_{INT}. A voltage difference V_{REF}-V_{INT} between the reference voltage V_{REF} and the initialization voltage V_{INT} may be stored in the storage capacitor C_{ST}.

In a sensing period, the high-level first scan signal SC and the high-level second scan signal SS may be maintained. For example, the initialization voltage line VL3 may be disconnected from a supply source of the initialization voltage V_{INT} and may function as a sensing line. The gate electrode of the first transistor T1 and the first electrode of the storage capacitor C_{ST} may maintain the reference voltage V_{REF} through the second transistor T2. Accordingly, in case that a current flows from the first electrode to the second electrode of the first transistor T1 and then the voltage of the second electrode becomes a “reference voltage V_{REF}-threshold voltage VTH”, the first transistor T1 may be turned off, and the initialization voltage line VL3 may be charged up to the “reference voltage V_{REF}-threshold voltage VTH”. Here, the threshold voltage VTH represents the threshold voltage VTH of the first transistor T1. The initialization voltage line VL3 charged with the “reference voltage V_{REF}-threshold voltage VTH” may be connected (e.g., electrically connected) to an external circuit, and the external circuit may sense the voltage of the initialization voltage line VL3 to extract the threshold voltage VTH of the first transistor T1. A data signal compensated based on characteristic information sensed during the sensing period may be generated, thereby compensating for a characteristic deviation of the first transistor T1 that may vary in pixels PX.

In a data input period, the high-level first scan signal SC may be supplied and the low-level second scan signal SS may be supplied, and the data voltage V_{DATA} from the data line DL may be supplied to the gate electrode of the first transistor T1 and the first electrode of the storage capacitor C_{ST} through the turned-on second transistor T2. The data voltage V_{DATA} may have a value compensated based on the sensing of the threshold voltage VTH of the first transistor T1, thereby correcting the characteristic deviation of the first transistor T1. In case that the data voltage V_{DATA} is applied, the second electrode of the first transistor T1 and the anode of the light emitting diode LED may substantially maintain the potential in the sensing period by the first transistor T1 in a turned-off state.

In a light emitting period, the first transistor T1 turned on by the data voltage V_{DATA} transmitted to the gate electrode of the first transistor may generate a driving current according to the data voltage V_{DATA}, and the light emitting diode LED may emit light by the driving current. For example, the luminance of the light emitting diode LED may be controlled by adjusting the driving current applied to the light emitting diode LED according to a magnitude (or amplitude) of the data voltage V_{DATA} applied to the pixel PX.

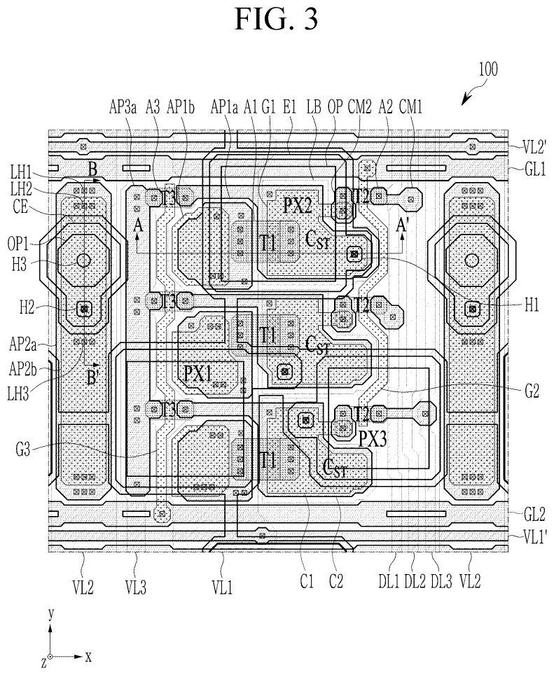

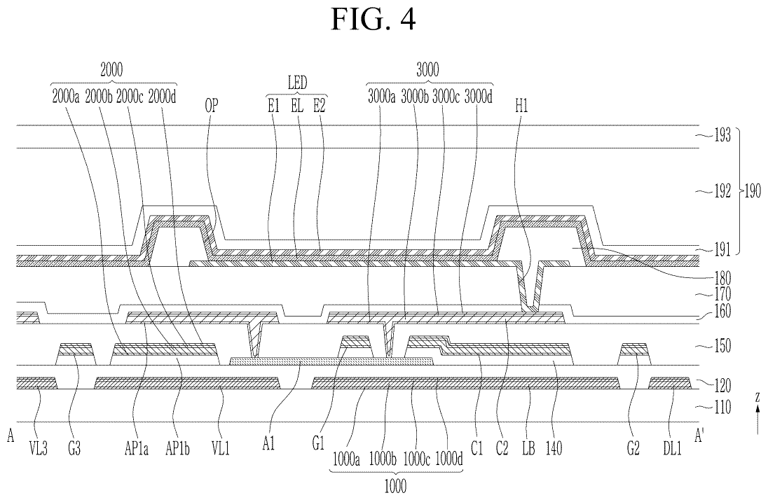

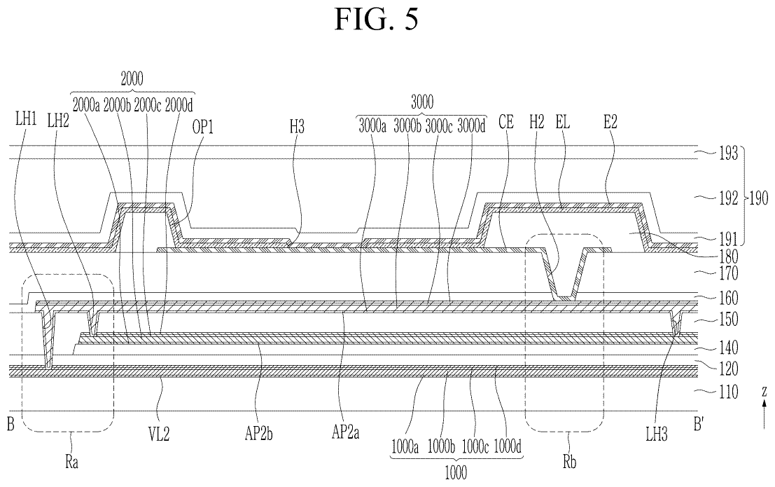

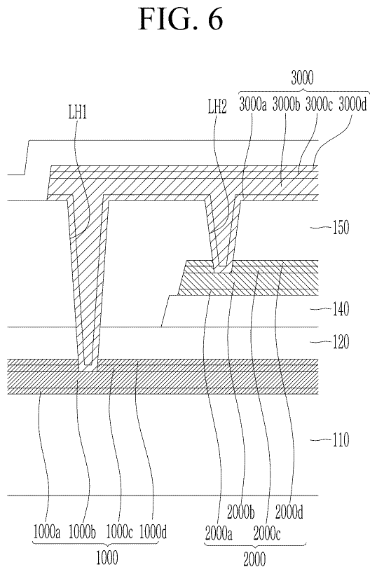

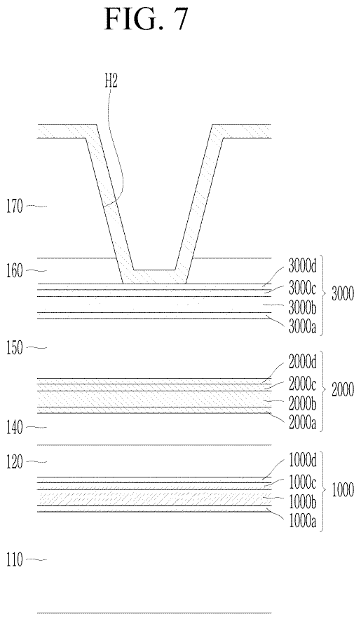

The display device according to an embodiment will be described in more detail with reference to FIGS. 3 to 7. FIG. 3 is a schematic plan view of a pixel area of the light emitting diode device according to an embodiment, FIG. 4 is a schematic cross-sectional view taken along line A-A′ of FIG. 3, FIG. 5 is a schematic cross-sectional view taken along line B-B′ of FIG. 3, FIG. 6 is a schematic enlarged view illustrating a part of FIG. 5, and FIG. 7 is a schematic enlarged view illustrating a part of FIG. 5.

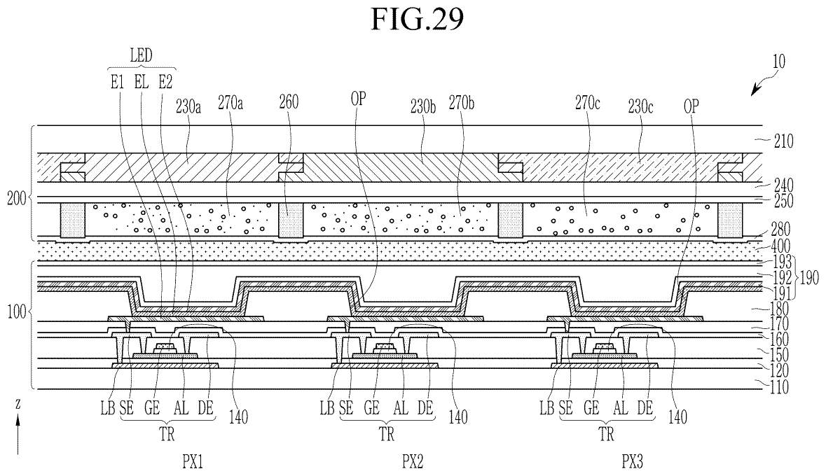

FIG. 3 illustrates three pixels PX1, PX2, and PX3 adjacent to each other and lines connected thereto in the display panel 10 included in the display device according to an embodiment. The pixels PX1, PX2, and PX3 may be disposed repeatedly in a matrix. The display unit 100 of the display panel 10 will be described, and the color conversion unit 200 of the display panel 10 will be described below with reference to FIG. 29.

Referring to FIGS. 3 to 7, the display unit 100 may include a light emitting diode LED corresponding to each of the pixels PX1, PX2, and PX3. The pixels PX1, PX2, and PX3 may include a first pixel PX1, a second pixel PX2, and a third pixel PX3 emitting different colors. For example, one of the first pixel PX1, the second pixel PX2, and the third pixel PX3 may display red, another may display green, and the other may display blue.

The display unit 100 may include a first substrate 110, first to third transistors T1, T2, and T3 and a storage capacitor C_{ST} formed on the first substrate 110, and a light emitting diode LED connected (e.g., electrically connected) to the first transistor T1.

The first substrate 110 may include a material having a rigid characteristic, such as glass, or a material having a flexible characteristic, such as plastic. For example, the first substrate 110 may be a glass substrate. The first substrate 110 may include a polymer material such as polyimide, polyamide, and polyethylene terephthalate.

A first conductive layer 1000 may be disposed on the first substrate 110. The first conductive layer 1000 may include data lines DL1, DL2, and DL3, a driving voltage line VL1, a common voltage line VL2, an initialization voltage line VL3, a light blocking pattern layer LB, and the like.

The data lines DL1, DL2, and DL3 may include a first data line DL1 transmitting the data voltage V_{DATA} to the first pixel PX1, a second data line DL2 transmitting the data voltage V_{DATA} to the second pixel PX2, and a third data line DL3 transmitting the data voltage V_{DATA} to the third pixel PX3. The first data line DL1, the second data line DL2, and the third data line DL3 may be disposed adjacent to each other in the first direction x and may extend in the second direction y.

The driving voltage line VL1 may transmit the driving voltage EL_{VDD}, the common voltage line VL2 may transmit the common voltage EL_{VSS}, and the initialization voltage line VL3 may transmit the initialization voltage V_{INT}. The driving voltage line VL1, the common voltage line VL2, and the initialization voltage line VL3 may each extend in the second direction y.

The common voltage line VL2, the initialization voltage line VL3, the driving voltage line VL1, and the data lines DL1, DL2, and DL3 may be repeatedly disposed along the first direction x. Accordingly, in the first direction x, the driving voltage line VL1 may be disposed between the initialization voltage line VL3 and the data lines DL1, DL2, and DL3, the common voltage line VL2 may be disposed between the data lines DL1, DL2, and DL3 and the initialization voltage line VL3, and the initialization voltage line VL3 may be disposed between the common voltage line VL2 and the driving voltage line VL1. The relative arrangement between the voltage lines VL1, VL2, and VL3 and the data lines DL1, DL2, and DL3 may be variously changed.

The light blocking pattern layer LB may be disposed between the driving voltage line VL1 and the data lines DL1, DL2, and DL3. The light blocking pattern layer LB may block external light from reaching a semiconductor layer A1 of the first transistor T1 to prevent deterioration of characteristics of the semiconductor layer A1. A leakage current of the first transistor T1 (e.g., a driving transistor) of which the current characteristic is important in the light emitting diode device, may be controlled by the light blocking pattern layer LB. The light blocking pattern layer LB may function as an electrode to which a specific voltage is applied. For example, in a saturation region of a voltage-current characteristic graph of the first transistor T1, a current change rate may be reduced, thereby improving the characteristics of the first transistor T1 (e.g., the driving transistor).

The first conductive layer 1000 may include a first layer 1000a, a second layer 1000b, a third layer 1000c, and a fourth layer 1000d.

The first layer 1000a of the first conductive layer 1000 may include a refractory metal such as molybdenum, chromium, tantalum and titanium. The second layer 1000b of the first conductive layer 1000 may include aluminum-based metal, silver-based metal, or copper-based metal having a low resistivity. The third layer 1000c of the first conductive layer 1000 may include a metal oxide including the same metal included in the second layer 1000b. The fourth layer 1000d of the first conductive layer 1000 may include transparent conductive oxide (TCO). For example, the first layer 1000a of the first conductive layer 1000 may include titanium, the second layer 1000b of the first conductive layer 1000 may include copper, the third layer 1000c of the first conductive layer 1000 may include copper oxide (CuOx), and the fourth layer 1000d of the first conductive layer 1000 may include at least one of indium tin oxide (ITO), zinc indium tin oxide (ZITO), indium zinc oxide (IZO), and aluminum zinc oxide (AZO).

The thickness of the second layer 1000b of the first conductive layer 1000 may be greater than the thickness of the first layer 1000a of the first conductive layer 1000 and the thickness of the fourth layer 1000d of the first conductive layer 1000. For example, the thickness of the fourth layer 1000d of the first conductive layer 1000 may be about 50 angstroms to about 1000 angstroms.

The first layer 1000a of the first conductive layer 1000 may include a refractory metal to increase the stability of the first conductive layer 1000, and the second layer 1000b of the first conductive layer 1000 may include a metal having a low resistivity to prevent the signal delay of the first conductive layer 1000. The first conductive layer 1000 further includes the third layer 1000c and the fourth layer 1000d in addition to the first layer 1000a and the second layer 1000b to decrease a change in taper angle of the side surface of the first conductive layer 1000 and reduce the roughness, thereby preventing disconnection or lifting of an insulating layer (e.g., a buffer layer 120) formed on the first conductive layer 1000 and preventing a signal line formed on the buffer layer 120 from being defective.

The buffer layer 120 may be disposed on the first conductive layer 1000. The buffer layer 120 may block impurities from the first substrate 110 in case that semiconductor layers A1, A2, and A3 are formed to improve the characteristics of the semiconductor layers A1, A2, and A3, and planarizes the surface of the first substrate 110 to mitigate the stress of the semiconductor layers A1, A2, and A3. The buffer layer 120 may include an inorganic insulating material such as silicon nitride (SiNₓ), silicon oxide (SiOₓ), or silicon oxynitride (SiOₓN_{y}). The buffer layer 120 may include amorphous silicon.

The semiconductor layers A1, A2, and A3 may be disposed above the buffer layer 120.

The semiconductor layers A1, A2, and A3 may include the semiconductor layer A1 of the first transistor T1, the semiconductor layer A2 of the second transistor T2, and the semiconductor layer A3 of the third transistor T3. The semiconductor layers A1, A2, and A3 may include a first region, a second region, and a channel region therebetween. The semiconductor layers A1, A2, and A3 may have a planar shape longer in the first direction x than in the second direction y. The first region of the semiconductor layer A1 may overlap the driving voltage line VL1 and may be connected (e.g., electrically connected) to the driving voltage line VL1. The second region and the channel region of the semiconductor layer A1 may overlap the light blocking pattern layer LB. The first region of the semiconductor layer A2 may be connected (e.g., electrically connected) to a corresponding data line among the data lines DL1, DL2, and DL3. For example, the first region of the semiconductor layer A1 of the first pixel PX1 may be connected (e.g., electrically connected) to the first data line DL1, the first region of the semiconductor layer A2 of the second pixel PX2 may be connected (e.g., electrically connected) to the second data line DL2, and the first region of the semiconductor layer A3 of the third pixel PX3 may be connected (e.g., electrically connected) to the third data line DL3. The second region of the semiconductor layer A2 may be connected (e.g., electrically connected) to the first storage electrode C1 of the storage capacitor C_{ST}. The first region of the semiconductor layer A3 may be connected (e.g., electrically connected) to the initialization voltage line VL3. The second region of the semiconductor layer A3 may be connected (e.g., electrically connected) to the second storage electrode C2 of the storage capacitor C_{ST}.

The semiconductor layer A1, A2, and A3 may include an oxide semiconductor. For example, the semiconductor layers A1, A2, and A3 may include an oxide semiconductor such as indium-gallium-zinc (IGZO) including at least one of zinc (Zn), indium (In), gallium (Ga), tin (Sn), and a mixture thereof. The semiconductor layers A1, A2, and A3 may include polycrystalline silicon or amorphous silicon, for example, low-temperature polysilicon (LTPS).

A first insulating layer 140 may be disposed on the semiconductor layers A1, A2, and A3. The first insulating layer 140 may be referred to as a gate insulating layer. The first insulating layer 140 may be formed in a region overlapping gate electrodes G1, G2, and G3, a first storage electrode C1, and first-second and second-second auxiliary pattern layers AP1b and AP2b. This structure may be formed by etching the first insulating layer 140 during a photolithography process for forming the gate electrodes G1, G2, and G3, the first storage electrode C1, and the first-second and second-second auxiliary pattern layers AP1b and AP2b. The first insulating layer 140 may substantially cover the entire first substrate 110. The first insulating layer 140 may be an inorganic insulating layer including an inorganic insulating material such as silicon oxide, silicon nitride, or silicon oxynitride, and may be a single layer or multi-layer.

A second conductive layer 2000 may be disposed on the first insulating layer 140. For example, the second conductive layer 2000 may include the gate electrode G1 of the first transistor T1, the gate electrode G2 of the second transistor T2, the gate electrode G3 of the third transistor T3, the first storage electrode C1 of the storage capacitor C_{ST}, the first-second auxiliary pattern layer AP1b connected (e.g., electrically connected) to the driving voltage line VL1, the second-second auxiliary pattern layer AP2b connected (e.g., electrically connected) to the common voltage line VL2, etc.

The gate electrodes G1, G2, and G3 may overlap channel regions of the corresponding semiconductor layers A1, A2, and A3. The gate electrode G1 may be connected (e.g., electrically connected) to the first storage electrode C1. The gate electrode G1 and the first storage electrode C1 may be integral with each other. The gate electrode G1 and the first storage electrode C1 may overlap the light blocking pattern layer LB. The first storage electrode C1 may be connected (e.g., electrically connected) to the second region of the semiconductor layer A2. The gate electrodes G2 of the second transistors T2 of the first pixel PX1, the second pixel PX2, and the third pixel PX3 may be connected (e.g., electrically connected) to each other and may be integral with each other. The gate electrodes G2 of the second transistors T2 of the first pixel PX1, the second pixel PX2 and the third pixel PX3 may extend substantially in the second direction y. The second transistors T2 of the first pixel PX1, the second pixel PX2, and the third pixel PX3 may receive the same first scan signal SC.

The gate electrodes G3 of the third transistors T3 of the first pixel PX1, the second pixel PX2, and the third pixel PX3 may be connected (e.g., electrically connected) to each other and may be integral with each other. The gate electrodes G3 of the third transistors T3 of the first pixel PX1, the second pixel PX2, and the third pixel PX3 may extend substantially in the second direction y. The third transistors T3 of the first pixel PX1, the second pixel PX2, and the third pixel PX3 may receive the same second scan signal SS.

The first-second auxiliary pattern layer AP1b connected (e.g., electrically connected) to the driving voltage line VL1 may overlap the driving voltage line VL1. The first-second auxiliary pattern layer AP1b may be disposed between the gate electrode G3 and the semiconductor layer A1 in the first direction x, e.g., in a plan view. First-second auxiliary pattern layers AP1b may be disposed to be spaced apart from each other in the second direction y. The first-second auxiliary pattern layer AP1b may be connected (e.g., electrically connected) to the driving voltage line VL1 to reduce the resistance of the driving voltage line VL1 and to reduce an RC delay of the driving voltage EL_{VDD}.

The second-second auxiliary pattern layer AP2b connected (e.g., electrically connected) to the common voltage line VL2 may overlap the common voltage line VL2. In a plan view, the second-second auxiliary pattern layer AP2b may overlap the common voltage line VL2 so as to be disposed (e.g., entirely disposed) within the common voltage line VL2. The second-second auxiliary pattern layer AP2b may be elongated in the second direction y and may be disposed between the first gate line GL1 and the second gate line GL2, e.g., in a plan view. The second-second auxiliary pattern layer AP2b may be repeatedly disposed in the second direction y. The second-second auxiliary pattern layer AP2b may be connected (e.g., electrically connected) to the common voltage line VL2 to reduce the resistance of the common voltage line VL2 and to reduce the RC delay of the common voltage EL_{VSS}.

The second conductive layer 2000 may include a first layer 2000a, a second layer 2000b, a third layer 2000c, and a fourth layer 2000d.

The first layer 2000a of the second conductive layer 2000 may include a refractory metal such as molybdenum, chromium, tantalum and titanium. The second layer 2000b of the second conductive layer 2000 may include an aluminum-based metal, a silver-based metal, or a copper-based metal having a low resistivity. The third layer 2000c of the second conductive layer 2000 may include a metal oxide including the same metal included in the second layer 2000b. The fourth layer 2000d of the second conductive layer 2000 may include transparent conductive oxide (TCO). For example, the first layer 2000a of the second conductive layer 2000 may include titanium. The second layer 2000b of the second conductive layer 2000 may include copper. The third layer 2000c of the second conductive layer 2000 may include copper oxide (CuOx). The fourth layer 2000d of the second conductive layer 2000 may include at least one of indium tin oxide (ITO), zinc indium tin oxide (ZITO), indium zinc oxide (IZO), and aluminum zinc oxide (AZO).

The thickness of the second layer 2000b of the second conductive layer 2000 may be greater than the thickness of the first layer 2000a of the second conductive layer 2000, the thickness of the third layer 2000c of the second conductive layer 2000, or the thickness of the fourth layer 2000d of the second conductive layer 2000. For example, the thickness of the fourth layer 2000d of the second conductive layer 2000 may be about 50 angstroms to about 1000 angstroms.

The first layer 2000a of the second conductive layer 2000 may include a refractory metal to increase the stability of the second conductive layer 2000. The second layer 2000b of the second conductive layer 2000 may include a metal having a low resistivity to prevent a signal delay of the second conductive layer 2000. The second conductive layer 2000 further includes the third layer 2000c and the fourth layer 2000d in addition to the first layer 2000a and the second layer 2000b to decrease a change in taper angle of the side surface of the second conductive layer 2000 and reduce the roughness, thereby preventing disconnection or lifting of an insulating layer (e.g., a second insulating layer 150) formed on the second conductive layer 2000 and preventing a signal line formed on the second insulating layer 150 from being defective.

The second insulating layer 150 may be disposed on the second conductive layer 2000. The second insulating layer 150 may be referred to as an interlayer insulating layer. The second insulating layer 150 may be an inorganic insulating layer including an inorganic insulating material such as silicon oxide, silicon nitride, or silicon oxynitride, and may be a single layer or multi-layer.

A third conductive layer 3000 may be disposed on the second insulating layer 150. The third conductive layer 3000 may include the first gate line GL1, the second gate line GL2, the second storage electrode C2 of the storage capacitor C_{ST}, an auxiliary driving voltage line VL1′, an auxiliary common voltage line VL2′, the first-first auxiliary pattern layer AP1a connected (e.g., electrically connected) to the driving voltage line VL1, the second-first auxiliary pattern layer AP2a connected (e.g., electrically connected) to the common voltage line VL2, the third auxiliary pattern layer AP3a connected (e.g., electrically connected) to the initialization voltage line VL3, etc.

The first gate line GL1 and the second gate line GL2 may extend in the first direction x. The first gate line GL1 may be connected (e.g., electrically connected) to the gate electrode G2 through a contact hole formed in the second insulating layer 150 and may apply a first scan signal SC. The second gate line GL2 may be connected (e.g., electrically connected) to the gate electrode G3 through the contact hole formed in the second insulating layer 150 and may apply a second scan signal SS.

The second storage electrode C2 of the storage capacitor C_{ST} may overlap the first storage electrode C1 and may form the storage capacitor C_{ST} together with the first storage electrode C1. The second storage electrode C2 may overlap the second region of the semiconductor layer A1, and the first storage electrode C1 may include an opening overlapping the second region of the semiconductor layer A1. The second storage electrode C2 may be connected (e.g., electrically connected) to the second region of the semiconductor layer A1 through the contact hole of the second insulating layer 150 and the opening of the first storage electrode C1. The second storage electrode C2 may be connected (e.g., electrically connected) to the light blocking pattern layer LB through the contact holes formed in the second insulating layer 150 and the buffer layer 120. Accordingly, the light blocking pattern layer LB, the first storage electrode C1 and the second storage electrode C2 may form a double storage capacitor C_{ST}. The second storage electrode C2 may include an extension portion that extends across the driving voltage line VL1 in the first direction x to overlap the second region of the semiconductor layer A3, and the extension portion of the second storage electrode C2 may be connected (e.g., electrically connected) to the second region of the semiconductor layer A3 through the contact hole formed in the second insulating layer 150.

The auxiliary driving voltage line VL1′ and the auxiliary common voltage line VL2′ may extend in the first direction x. The auxiliary driving voltage line VL1′ may be connected (e.g., electrically connected) to the driving voltage line VL1 through the contact holes formed in the second insulating layer 150 and the buffer layer 120. The auxiliary common voltage line VL2′ may be connected (e.g., electrically connected) to the common voltage line VL2 through the contact holes formed in the second insulating layer 150 and the buffer layer 120. Accordingly, the lines transmitting the driving voltage EL_{VDD} may be connected (e.g., electrically connected) to each other in a mesh form in the display area DA, and may provide a uniform driving voltage EL_{VDD} throughout the display area DA. For example, the lines transmitting the common voltage EL_{VSS} may be connected (e.g., electrically connected) to each other in a mesh shape in the display area DA, and may provide a uniform common voltage EL_{VSS} throughout the display area DA.

The first-first auxiliary pattern layer AP1a connected (e.g., electrically connected) to the driving voltage line VL1 may overlap the driving voltage line VL1 and the first-second auxiliary pattern layer AP1b. The first-first auxiliary pattern layer AP1a may be disposed between the gate electrode G3 and the semiconductor layer A1 in the first direction x, e.g., in a plan view. First-first auxiliary pattern layers AP1a may be disposed to be spaced apart from each other in the second direction y. The first-first auxiliary pattern layer AP1a may be connected (e.g., electrically connected) to the driving voltage line VL1 to reduce the resistance of the driving voltage line VL1 and reduce the RC delay of the driving voltage EL_{VDD}. The first-first auxiliary pattern layer AP1a may be connected (e.g., electrically connected) to the first-second auxiliary pattern layer AP1b through the contact hole formed in the second insulating layer 150, may be connected (e.g., electrically connected) to the driving voltage line VL1 through the contact holes formed in the second insulating layer 150 and the buffer layer 120, and may be connected (e.g., electrically connected) to the first region of the semiconductor layer A1 through the contact hole formed in the second insulating layer 150. Accordingly, the first-second auxiliary pattern layer AP1b and the first transistor T1 may be connected (e.g., electrically connected) to the driving voltage line VL1 through the first-first auxiliary pattern layer AP1a, respectively.

The second-first auxiliary pattern layer AP2a connected (e.g., electrically connected) to the common voltage line VL2 may overlap the common voltage line VL2 and the second-second auxiliary pattern layer AP2b. In a plan view, the second-first auxiliary pattern layer AP2a may overlap the common voltage line VL2 so as to be disposed (e.g., entirely disposed) within the common voltage line VL2. The second-first auxiliary pattern layer AP2a may overlap the second-second auxiliary pattern layer AP2b to cover the entire second-second auxiliary pattern layer AP2b. The second-first auxiliary pattern layer AP2a may be elongated in the second direction y and may be disposed between the first gate line GL1 and the second gate line GL2, e.g., in a plan view. The second-first auxiliary pattern layer AP2a may be repeatedly disposed in the second direction y. The second-first auxiliary pattern layer AP2a may be connected (e.g., electrically connected) to the common voltage line VL2 to reduce the resistance of the common voltage line VL2 and to reduce the RC delay of the common voltage EL_{VSS}. The second-first auxiliary pattern layer AP2a may be connected (e.g., electrically connected) to the common voltage line VL2 through a contact hole LH1 formed in the second insulating layer 150 and the buffer layer 120 and connected (e.g., electrically connected) to the second-second auxiliary pattern layer AP2b through a contact hole LH2 formed in the second insulating layer 150. Accordingly, the second-second auxiliary pattern layer AP2b may be connected (e.g., electrically connected) to the common voltage line VL2 through the second-first auxiliary pattern layer AP2a.

The third auxiliary pattern layer AP3a connected (e.g., electrically connected) to the initialization voltage line VL3 may overlap the initialization voltage line VL3. The third auxiliary pattern layer AP3a may be elongated in the second direction y and may be disposed between the first gate line GL1 and the second gate line GL2, e.g., in a plan view. The third auxiliary pattern layer AP3a may be repeatedly disposed in the second direction y. The third auxiliary pattern layer AP3a may be connected (e.g., electrically connected) to the initialization voltage line VL3 to reduce resistance of the initialization voltage line VL3 and to reduce the RC delay of the initialization voltage V_{INT}. The third auxiliary pattern layer AP3a may be connected (e.g., electrically connected) to the initialization voltage line VL3 through the contact holes formed in the second insulating layer 150 and the buffer layer 120 and may be connected (e.g., electrically connected) to the first region of the semiconductor layer A3 through the contact hole formed in the second insulating layer 150. Accordingly, the third transistor T3 may be connected (e.g., electrically connected) to the initialization voltage line VL3 through the third auxiliary pattern layer AP3a.

The third conductive layer 3000 may further include a connection member CM1 connecting the first region of the semiconductor layer A2 with the data lines DL1, DL2, and DL3, and a connection member CM2 connecting the second region of the semiconductor layer A2 with the first storage electrode C1 of the storage capacitor C_{ST}. The connection member CM1 may be connected (e.g., electrically connected) to the data lines DL1, DL2, and DL3 through the contact holes formed in the second insulating layer 150 and the buffer layer 120 and may be connected (e.g., electrically connected) to the first region of the semiconductor layer A2 through the contact hole formed in the second insulating layer 150. The connection member CM2 may be connected (e.g., electrically connected) to the first storage electrode C1 through a contact hole formed in the second insulating layer 150 and may be connected (e.g., electrically connected) to the semiconductor layer A2 through the contact hole formed in the second insulating layer 150. Accordingly, the second transistor T2 may be connected (e.g., electrically connected) to the data lines DL1, DL2, and DL3 through the connection member CM1 and may be connected (e.g., electrically connected) to the first storage electrode C1 through the connection member CM2.

The first layer 3000a of the third conductive layer 3000 may include a refractory metal such as molybdenum, chromium, tantalum and titanium. The second layer 3000b of the third conductive layer 3000 may include an aluminum-based metal, a silver-based metal, or a copper-based metal having a low resistivity. The third layer 3000c of the third conductive layer 3000 may include a metal oxide including the same metal included in the second layer 3000b or the third layer 3000c of the third conductive layer 3000 may include a refractory metal. The fourth layer 3000d of the third conductive layer 3000 may include transparent conductive oxide (TCO). For example, the first layer 3000a of the third conductive layer 3000 may include titanium. The second layer 3000b of the third conductive layer 3000 may include copper. The third layer 3000c of the third conductive layer 3000 may include copper oxide (CuOx) or titanium. The fourth layer 3000d of the third conductive layer 3000 may include at least one of indium tin oxide (ITO), zinc indium tin oxide (ZITO), indium zinc oxide (IZO), and aluminum zinc oxide (AZO).

The thickness of the second layer 3000b of the third conductive layer 3000 may be greater than the thickness of the first layer 3000a of the third conductive layer 3000, the thickness of the third layer 3000c of the third conductive layer 3000, or the thickness of the fourth layer 3000d of the third conductive layer 3000. For example, the thickness of the third layer 3000c of the third conductive layer 3000 or the thickness of the fourth layer 3000d of the third conductive layer 3000 may be about 50 angstroms to about 1000 angstroms.

The first layer 3000a of the third conductive layer 3000 may include a refractory metal to increase the stability of the third conductive layer 3000. The second layer 3000b of the third conductive layer 3000 may include a metal having a low resistivity to prevent the signal delay of the third conductive layer 3000. The third conductive layer 3000 further includes the third layer 3000c and the fourth layer 3000d in addition to the first layer 3000a and the second layer 3000b to decrease a change in taper angle of the side surface of the third conductive layer 3000 and reduce the roughness, thereby preventing disconnection or lifting of an insulating layer (e.g., a third insulating layer 160) formed on the third conductive layer 3000.

The third insulating layer 160 may be disposed on the third conductive layer. The third insulating layer 160 may be referred to as a passivation layer. The third insulating layer 160 may be an inorganic insulating layer including an inorganic insulating material such as silicon oxide, silicon nitride, or silicon oxynitride, and may be a single layer or multi-layer.

A first organic insulating layer 170 may be disposed on the third insulating layer 160. The first organic insulating layer 170 may be referred to as a planarization layer. The first organic insulating layer 170 may include an organic insulating material, such as a general-purpose polymer such as Poly(methyl methacrylate) and polystyrene, a polymer derivative having a phenolic group, an acrylic polymer, an imide-based polymer (e.g., polyimide), and a siloxane-based polymer.

A fourth conductive layer may include a pixel electrode E1, a connection electrode CE, and the like of the light emitting diode LED. The fourth conductive layer may be disposed on the first organic insulating layer 170.

The pixel electrode E1 may be connected (e.g., electrically connected) to the second storage electrode C2 through a contact hole H1 formed in the first organic insulating layer 170. The pixel electrode E1 may be connected (e.g., electrically connected) to the second region of the semiconductor layer A1 through the second storage electrode C2.

The connection electrode CE may overlap the common voltage line VL2 and the second-first and second-second auxiliary pattern layers AP2a and AP2b. The connection electrode CE may be connected (e.g., electrically connected) to the second-first auxiliary pattern layer AP2a connected (e.g., electrically connected) to the common voltage line VL2 through a contact hole H2 formed in the first organic insulating layer 170 and the third insulating layer 160. The contact hole H2 may be spaced apart from an opening OP1 in the second direction y.

In a plan view, the connection electrode CE may include a portion formed in an octagonal shape and a portion protruding from one side of the octagonal shape toward the contact hole H2.

The fourth conductive layer may be formed of a reflective conductive material or a semi-transmissive conductive material or may be formed of a transparent conductive material. The pixel electrode E1 may include a transparent conductive material such as indium tin oxide (ITO) or indium zinc oxide (IZO). The pixel electrode E1 may include a metal such as lithium (Li), calcium (Ca), aluminum (A1), silver (Ag), magnesium (Mg), or gold (Au). The pixel electrode E1 may have a multi-layer structure, for example, a triple-layer structure such as ITO/silver (Ag)/ITO.

A second organic insulating layer 180 may be disposed on the fourth conductive layer. The second organic insulating layer 180 may be referred to as a pixel defining layer. The second organic insulating layer 180 may include an organic insulating material such as an acryl-based polymer, an imide-based polymer, or an amide-based polymer. The second organic insulating layer 180 may include a black pigment. For example, the second organic insulating layer 180 may include a polyimide binder and a mixed pigment of red, green, and blue. The second organic insulating layer 180 may include a cardo binder resin and a mixture of a lactam black pigment and a blue pigment. The second organic insulating layer 180 may include carbon black. The second organic insulating layer 180 including the black pigment may improve a contrast ratio and may prevent reflection by a metal layer disposed therebelow.

The second organic insulating layer 180 may cover an edge portion of the pixel electrode E1 and an edge portion of the connection electrode CE. The second organic insulating layer 180 may be removed in a region other than a region covering the edge portion of the pixel electrode E1 and the edge portion of the connection electrode CE. The second organic insulating layer 180 may have an opening OP overlapping the pixel electrode E1 and an opening OP1 overlapping the connection electrode CE. The openings OP and OP1 may be regions in which the second organic insulating layer 180 is removed in a third direction z (e.g., a thickness direction).

An emission layer EL may be disposed on the fourth conductive layer. The emission layer EL may be disposed over the pixels PX1, PX2, and PX3. The emission layer EL may be continuously disposed throughout the display area DA. The emission layer EL may be in contact with the pixel electrode E1 through the opening OP of the second organic insulating layer 180. The emission layer EL may have a contact hole H3 overlapping the opening OP1. The contact hole H3 may overlap the common voltage line VL2 and the second-first and second-second auxiliary pattern layers AP2a and AP2b. In a plan view, the contact hole H3 may be disposed in the opening OP1. The contact hole H3 may have a narrower width than the opening OP1. The contact hole H3 may have a circular or elliptical planar shape but is not limited thereto.

The emission layer EL may include a light emitting material emitting blue light. The emission layer EL may include a light emitting material that emits red light or green light in addition to blue light. The emission layer EL may include emission layers, and the plurality of emission layers may include emission layers emitting light of the same color or emission layers emitting light of different colors. For example, the emission layer EL may have a structure in which three blue emission layers are stacked. As another example, the emission layer EL may have a structure in which three blue emission layers and one green emission layer are stacked. At least one of a hole injection layer, a hole transport layer, an electron transport layer, and an electron injection layer may be disposed on the pixel electrode E1 in addition to the emission layer EL.

A common electrode E2 may be disposed on the emission layer EL. The common electrode E2 may be disposed across the pixels PX1, PX2, and PX3. The common electrode E2 may be continuously disposed throughout the display area DA. The common electrode E2 may be connected (e.g., electrically connected) to the connection electrode CE through a contact hole H3 formed in the emission layer EL. Since the connection electrode CE is connected (e.g., electrically connected) to the common voltage line VL2, the common electrode E2 may be connected (e.g., electrically connected) to the common voltage line VL2 through the connection electrode CE to receive the common voltage EL_{VSS}. Accordingly, the common electrode E2 may receive the common voltage EL_{VSS} uniformly throughout the display area DA, and may prevent (or minimize) a voltage drop due to the resistance of the common electrode E2, and prevent a luminance deviation from occurring in the display area DA.

The contact hole H3 formed in the emission layer EL to connect the common electrode E2 to the connection electrode CE may be formed by a laser drilling process. For example, the contact hole H3 penetrating through the emission layer EL in the third direction z, which is the thickness direction, may be formed by forming the emission layer EL and removing a portion of the emission layer EL overlapping the opening OP1 by irradiating a laser. Accordingly, the connection electrode CE overlapping the contact hole H3 may be exposed. Thereafter, in case that the common electrode E2 is formed, the common electrode E2 may be connected (e.g., electrically connected) to the connection electrode CE through the contact hole H3.

The common electrode E2 may include a metal such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), and lithium (Li). The common electrode E2 may include transparent conductive oxide such as indium tin oxide (ITO) or indium zinc oxide (IZO). The common electrode E2 may have a multi-layer structure, for example, a double-layer structure such as magnesium (Mg)/silver (Ag).

The pixel electrode E1, the emission layer EL, and the common electrode E2 may form a light emitting diode LED (e.g., an organic light emitting diode). The pixel electrode E1 may be individually provided for each of the pixels PX1, PX2, and PX3 to receive a driving current. The common electrode E2 may be provided in common in the pixels PX1, PX2, and PX3 to receive a common voltage. The pixel electrode E1 may be an anode that is a hole injection electrode, and the common electrode E2 may be a cathode that is an electron injection electrode, and vice versa. The opening OP of the second organic insulating layer 180 may correspond to a light emitting region of the light emitting diode LED.

An encapsulation layer 190 may be disposed on the common electrode E2. The encapsulation layer 190 may seal the light emitting diodes LED and may prevent moisture or oxygen from penetrating from the outside. The encapsulation layer 190 may cover the entire display area DA, and an edge portion of the encapsulation layer 190 may be disposed in the non-display area NA.

The encapsulation layer 190 may be a thin film encapsulation layer including a first inorganic layer 191, an organic layer 192, and a second inorganic layer 193. The first inorganic layer 191 and the second inorganic layer 193 may prevent penetration of moisture, etc., and the organic layer 192 may planarize the surface of the encapsulation layer 190, e.g., the surface of the second inorganic layer 193 in the display area DA. The first inorganic layer 191 and the second inorganic layer 193 may include an inorganic insulating material such as silicon oxide or silicon nitride. The organic layer 192 may include an organic material such as an acrylic resin, a methacrylic resin, polyisoprene, a vinyl resin, an epoxy resin, a urethane resin, a cellulose resin, or a perylene resin.

The first inorganic layer 191 and the second inorganic layer 193 may be wider than the organic layer 192, and the first inorganic layer 191 and the second inorganic layer 193 may be in contact with each other near the edge portion of the encapsulation layer 190. An edge portion of the first inorganic layer 191 and an edge portion of the second inorganic layer 193 may substantially coincide with each other. As the first inorganic layer 191 and the second inorganic layer 193 have wide widths, penetration of moisture or oxygen from the side surface of the display area DA may be prevented, and the penetration of moisture or oxygen may be delayed by making a penetration path of moisture or oxygen long and complicated.

As described above, for the connection of signal lines disposed on different layers, the plurality of contact holes LH1 overlapping the first conductive layer 1000 may be formed in the second insulating layer 150 and the buffer layer 120. The plurality of contact holes LH2 and LH3 overlapping the second conductive layer 2000 may be formed in the second insulating layer 150. The plurality of contact holes H1 and H2 overlapping the third conductive layer 3000 may be formed in the third insulating layer 160 and the first organic insulating layer 170.

Referring to FIG. 6 of an enlarged first region Ra of FIG. 5 in addition to FIGS. 3 to 5, the third layer 1000c and the fourth layer 1000d of the first conductive layer 1000 may be removed from portions overlapping the plurality of contact holes LH1 overlapping the second insulating layer 150 and the buffer layer 120, e.g., to expose the second layer 1000b of the first conductive layer 1000. The third layer 2000c and the fourth layer 2000d of the second conductive layer 2000 may be removed from portions overlapping the plurality of contact holes LH2 and LH3 formed in the second insulating layer 150, e.g., to expose the second layer 2000b of the second conductive layer 2000.

The third layer 1000c and the fourth layer 1000d of the first conductive layer 1000 may be removed from the portions overlapping the plurality of contact holes LH1. Thus, the second layer 1000b of the first conductive layer 1000 having a low resistivity may be connected (e.g., electrically connected) to another layer through the plurality of contact holes LH1, thereby preventing the signal delay at the contact portions of the signal lines.

The third layer 2000c and the fourth layer 2000d of the second conductive layer 2000 may be removed from the portions overlapping the plurality of contact holes LH1. Thus, the second layer 1000b of the first conductive layer 1000 having a low resistivity may be connected (e.g., electrically connected) to another layer through the plurality of contact holes LH2 and LH3, thereby preventing the signal delay at the contact portions of the signal lines.

Referring to FIG. 7 of an enlarged second region Rb of FIG. 5 in addition to FIGS. 3 to 5, the third layer 3000c and the fourth layer 3000d of the third conductive layer 3000 may not be removed from a portion overlapping the plurality of contact holes H1 and H2 formed in the third insulating layer 160 and the first organic insulating layer 170. The third layer 3000c and the fourth layer 3000d of the third conductive layer 3000 are not removed from the portions overlapping the plurality of contact holes H1 and H2, so that contact characteristics of the pixel electrode E1 and the connection electrode CE in contact with the third conductive layer 3000 may be increased.

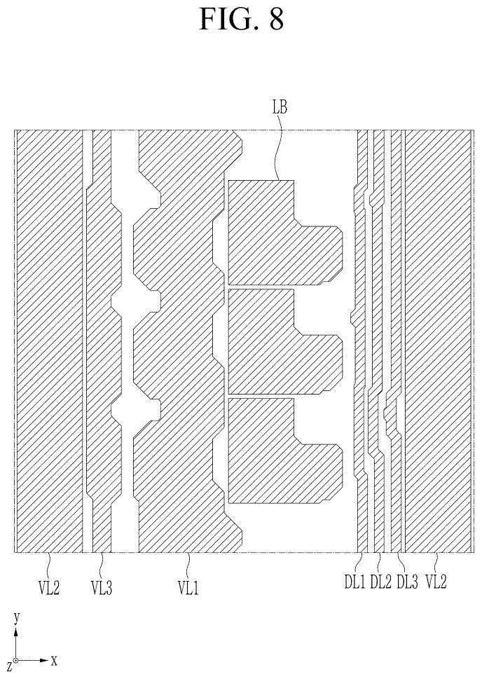

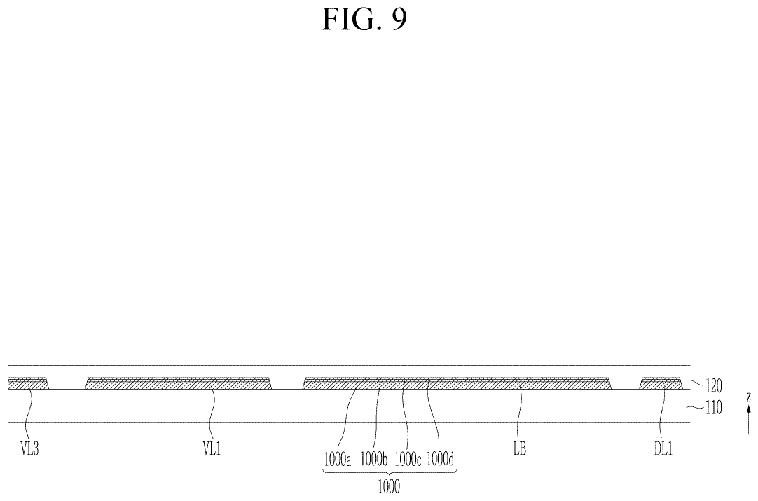

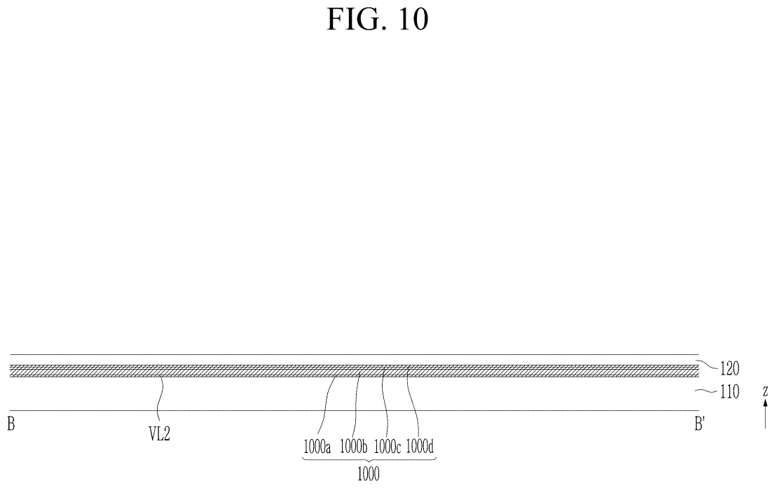

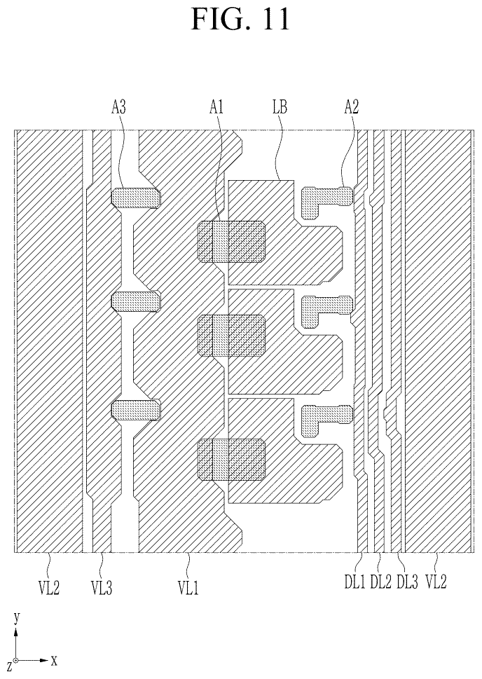

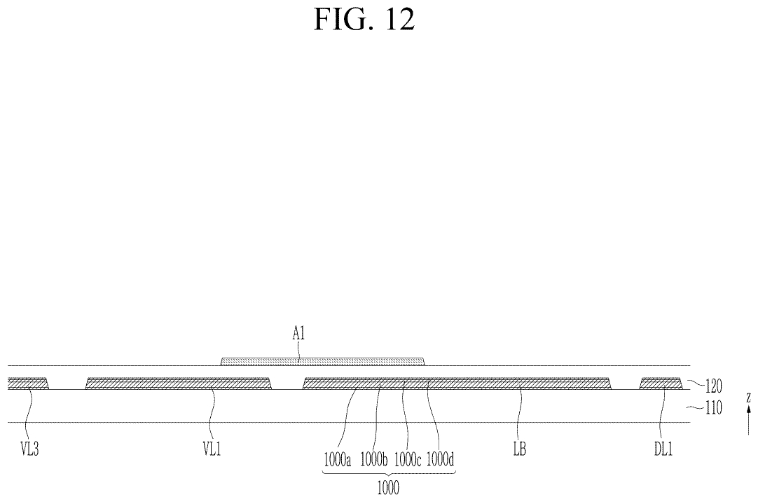

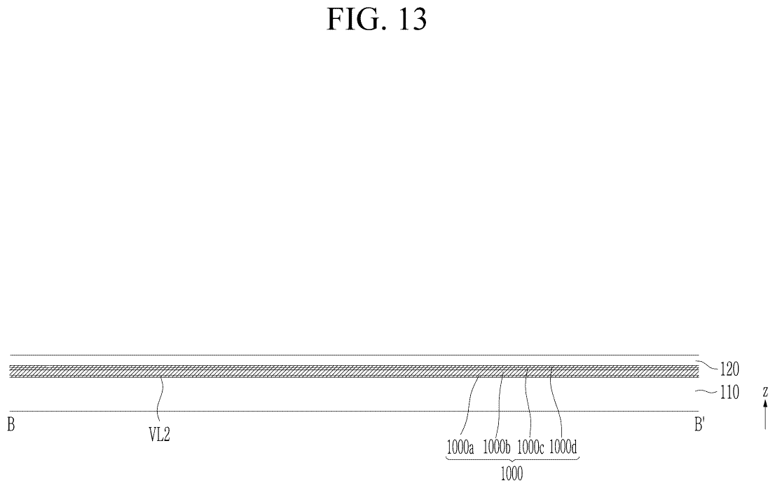

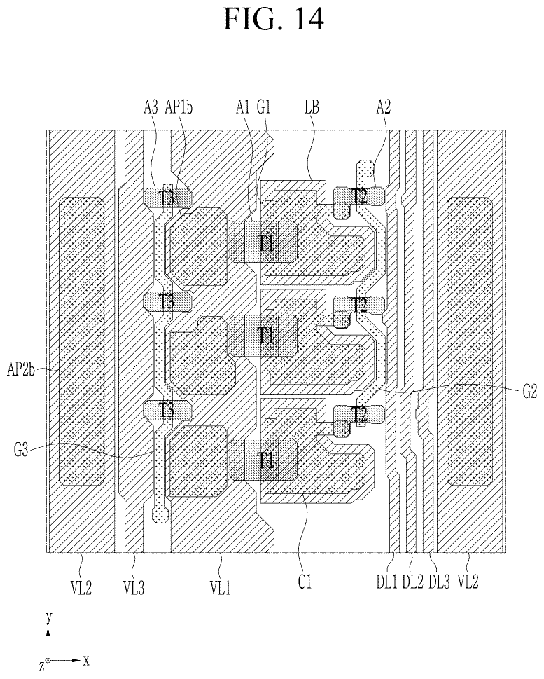

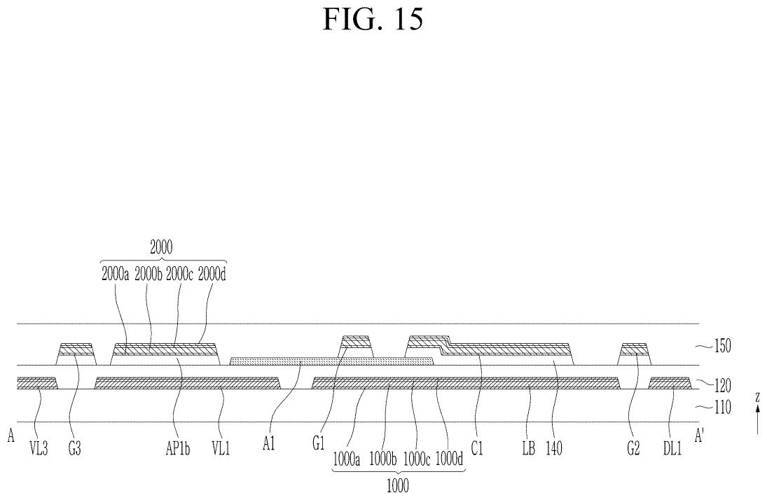

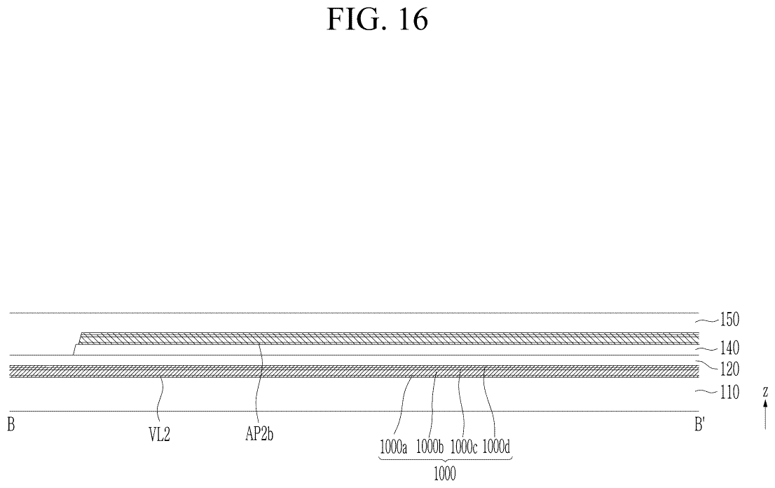

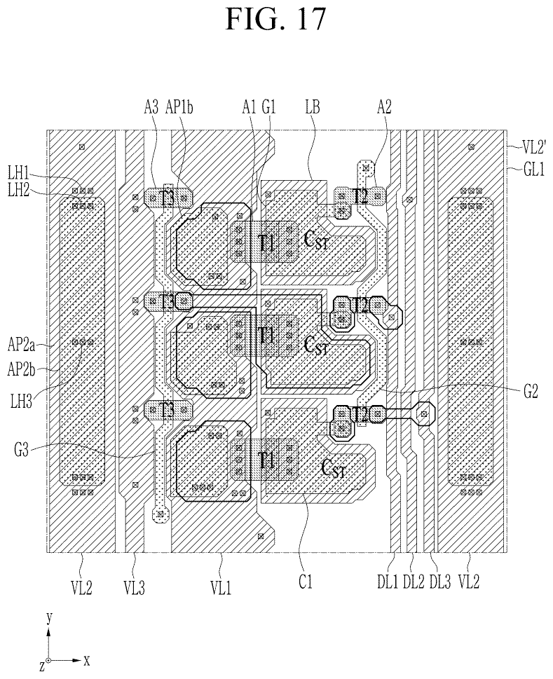

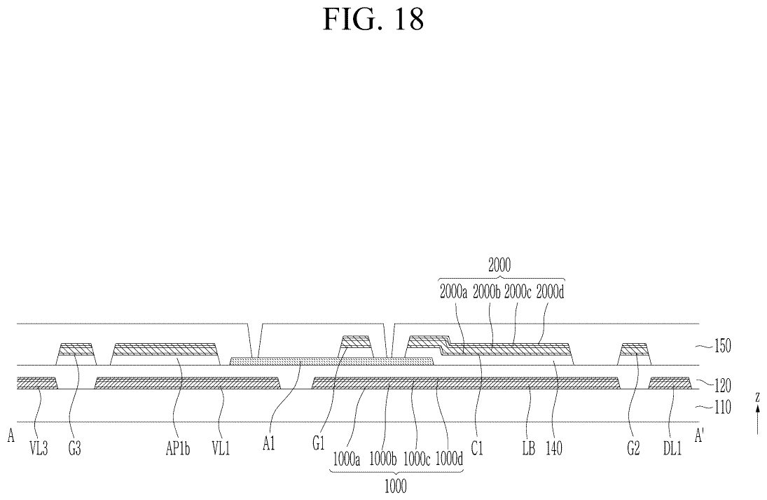

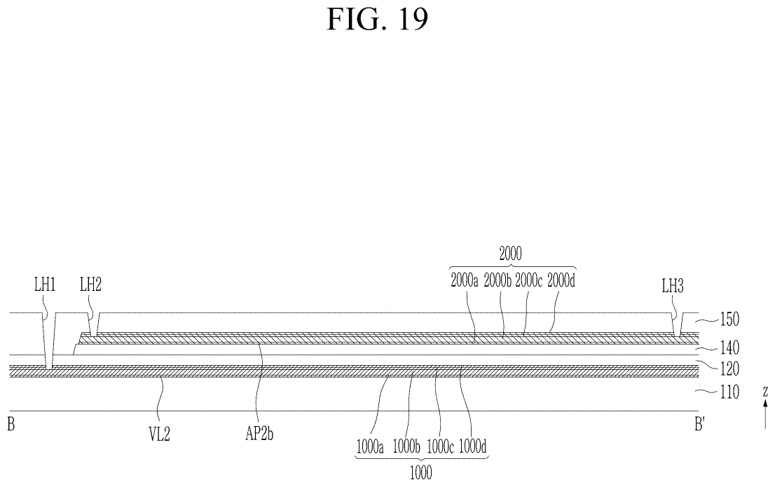

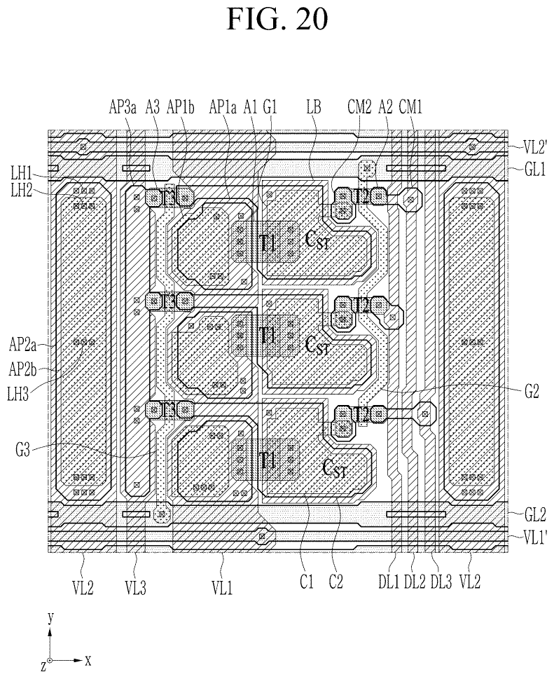

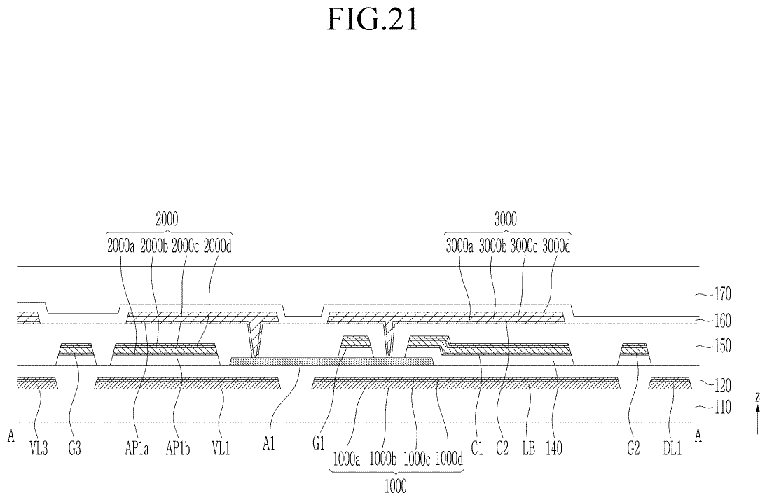

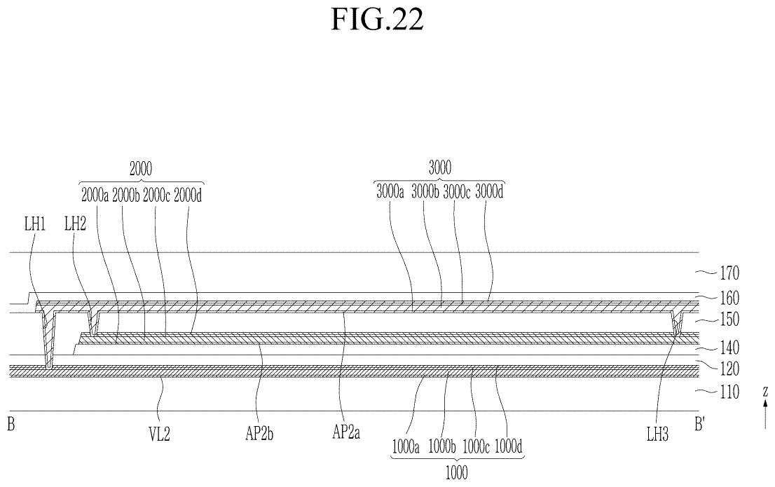

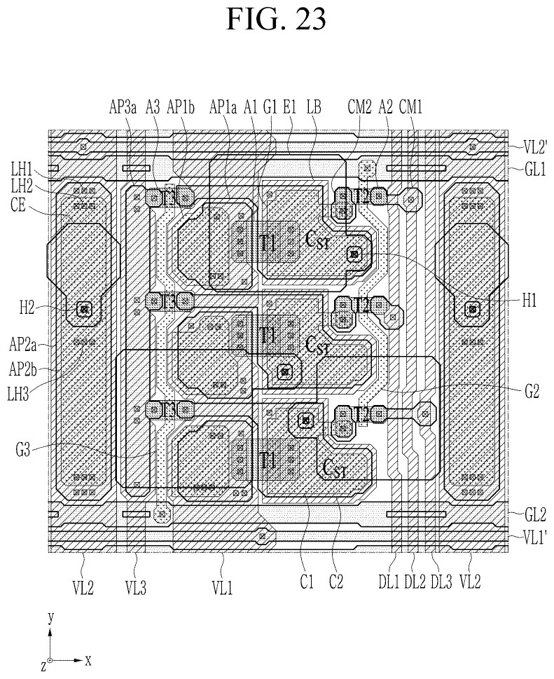

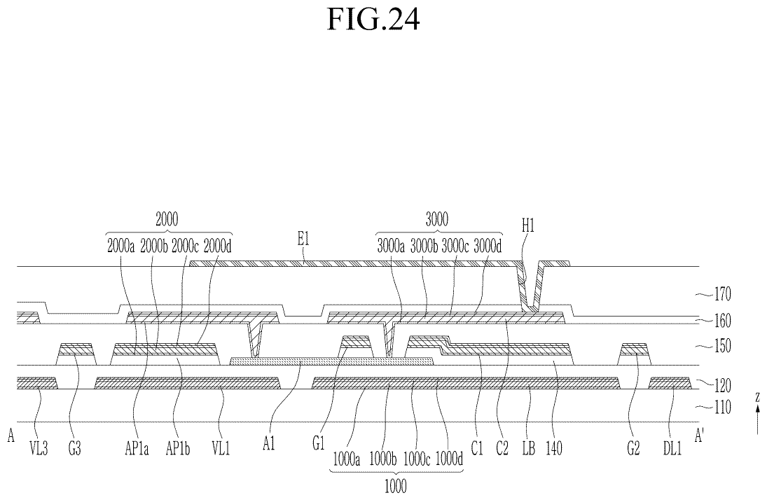

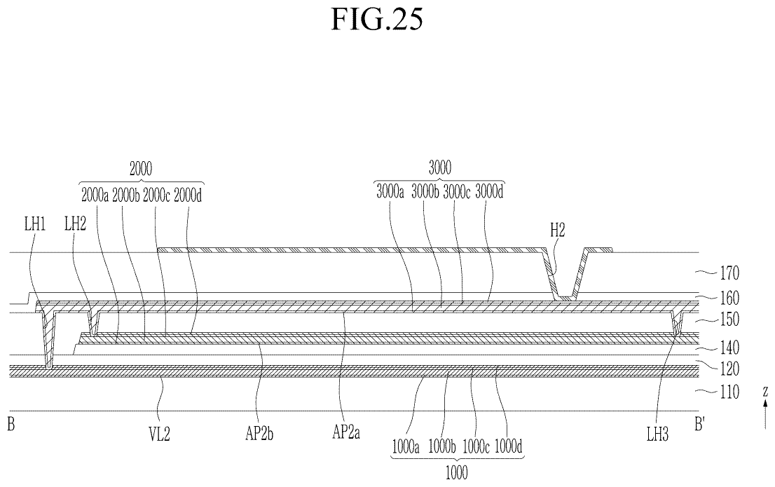

A method of manufacturing a display device according to an embodiment will be described with reference to FIGS. 8 to 25 along with FIGS. 3 to 7. FIGS. 8, 11, 14, 17, 20 and 23 are schematic plan views illustrating the light emitting diode device illustrated in FIG. 3 according to a manufacturing sequence. FIGS. 9 and 10 are schematic cross-sectional views illustrating a part of FIG. 8, FIGS. 12 and 13 are schematic cross-sectional views illustrating a part of FIG. 11, FIGS. 15 and 16 are schematic cross-sectional views illustrating a part of FIG. 14, FIGS. 18 and 19 are schematic cross-sectional views illustrating a part of FIG. 17, FIGS. 21 and 22 are schematic cross-sectional views illustrating a part of FIG. 20, and FIGS. 24 and 25 are schematic cross-sectional views illustrating a part of FIG. 23.

Referring to FIGS. 8 to 10, the first conductive layer 1000 may include the data lines DL1, DL2, and DL3, the driving voltage line VL1, the common voltage line VL2, the initialization voltage line VL3, the light blocking pattern layer LB, and the like. The first conductive layer 1000 may be formed on the first substrate 110, and the buffer layer 120 may be formed on the first conductive layer 1000. In FIG. 8, the first conductive layer 1000 is illustrated.

The first layer 1000a of the first conductive layer 1000, which includes a refractory metal, for example, titanium may be stacked on the first substrate 110. The second layer 1000b including a metal having a low resistivity, for example, copper, may be stacked on the first layer 1000a. The fourth layer 1000d, which includes transparent conductive oxide (TCO) such as indium tin oxide (ITO), zinc indium tin oxide (ZITO), indium zinc oxide (IZO), and aluminum zinc oxide (AZO), may be stacked on the second layer 1000b. Thus, an upper surface of the second layer 1000b may be in contact with the fourth layer 1000d, and a part of the upper surface of the second layer 1000b in contact with the fourth layer 1000d may be oxidized. Thus, the third layer 1000c including a metal oxide of the first conductive layer 1000 may be formed.

The thickness of the second layer 1000b of the first conductive layer 1000 may be greater than the thickness of the first layer 1000a of the first conductive layer 1000 and the thickness of the fourth layer 1000d of the first conductive layer 1000. For example, the thickness of the fourth layer 1000d of the first conductive layer 1000 may be about 50 angstroms to about 1000 angstroms.

The first conductive layer 1000 including the first layer 1000a, the second layer 1000b, the third layer 1000c, and the fourth layer 1000d may be stacked and etched to form the data lines DL1, DL2, and DL3, the driving voltage line VL1, the common voltage line VL2, the initialization voltage line VL3, the light blocking pattern layer LB, and the like, and the buffer layer 120 may be formed on the first conductive layer 1000.

The first layer 1000a of the first conductive layer 1000 may include a refractory metal to increase the stability of the first conductive layer 1000. The second layer 1000b of the first conductive layer 1000 may include a metal having a low resistivity to prevent the signal delay of the first conductive layer 1000. The first conductive layer 1000 may further include the third layer 1000c and the fourth layer 1000d in addition to the first layer 1000a and the second layer 1000b to decrease a change in taper angle of the side surface of the first conductive layer 1000 and reduce the roughness, thereby preventing disconnection or lifting of an insulating layer (e.g., the buffer layer 120) formed on the first conductive layer 1000 and preventing a signal line formed on the buffer layer 120 from being defective.

Referring to FIGS. 11 to 13, the semiconductor layer A1, A2, and A3 may be formed on the buffer layer 120. In FIG. 11, the semiconductor layers A1, A2, and A3 are illustrated.

The semiconductor layers A1, A2, and A3 may include the semiconductor layer A1 of the first transistor T1, the semiconductor layer A2 of the second transistor T2, and the semiconductor layer A3 of the third transistor T3. The semiconductor layers A1, A2, and A3 may include a first region, a second region, and a channel region therebetween. The semiconductor layers A1, A2, and A3 may have a planar shape longer in the first direction x than in the second direction y. The first region of the semiconductor layer A1 may overlap the driving voltage line VL1 and may be connected (e.g., electrically connected) to the driving voltage line VL1. The second region and the channel region of the semiconductor layer A1 may overlap the light blocking pattern layer LB. The first region of the semiconductor layer A2 may be connected (e.g., electrically connected) to a corresponding data line among the data lines DL1, DL2, and DL3.

The semiconductor layer A1, A2, and A3 may include an oxide semiconductor. For example, the semiconductor layers A1, A2, and A3 may include an oxide semiconductor such as indium-gallium-zinc (IGZO) including at least one of zinc (Zn), indium (In), gallium (Ga), tin (Sn), and a mixture thereof. The semiconductor layers A1, A2, and A3 may include polycrystalline silicon or amorphous silicon, for example, low-temperature polysilicon (LTPS).

Referring to FIGS. 14 to 16, the first insulating layer 140, the second conductive layer 2000, and the second insulating layer 150 may be formed on the semiconductor layers A1, A2, and A3. In FIG. 14, the second conductive layer 2000 is illustrated.

The first insulating layer 140 including an inorganic insulating material such as silicon oxide, silicon nitride, silicon nitroxide may be stacked. The first layer 2000a of the second conductive layer 2000 including a refractory metal, for example, titanium may be stacked on the first insulating layer 140, the second layer 2000b including a metal having a low resistivity, for example, copper, may be stacked on the first layer 2000a, and the fourth layer 2000d including transparent conductive oxide (TCO) such as indium tin oxide (ITO), zinc indium tin oxide (ZITO), indium zinc oxide (IZO), or aluminum zinc oxide (AZO) may be stacked on the second layer 2000b. Thus, an upper surface of the second layer 2000b may be in contact with the fourth layer 2000d, and a part of the upper surface of the second layer 2000b in contact with the fourth layer 2000d may be oxidized. Thus, the third layer 2000c including a metal oxide of the second conductive layer 2000 may be formed.

The thickness of the second layer 2000b of the second conductive layer 2000 may be greater than the thickness of the first layer 2000a of the second conductive layer 2000 and the thickness of the fourth layer 2000d of the second conductive layer 2000. For example, the thickness of the fourth layer 2000d of the second conductive layer 2000 may be about 50 angstroms to about 1000 angstroms.

The first insulating layer 140 may be stacked. The second conductive layer 2000 including the first layer 2000a, the second layer 2000b, the third layer 2000c, and the fourth layer 2000d may be stacked on the first insulating layer 140. The first insulating layer 140 and the second conductive layer 2000 may be etched to form the gate electrode G1 of the first transistor T1, the gate electrode G2 of the second transistor T2, the gate electrode G3 of the third transistor T3, the first storage electrode C1 of the storage capacitor C_{ST}, the first-second auxiliary pattern layer AP1b connected (e.g., electrically connected) to the driving voltage line VL1, the second-second auxiliary pattern layer AP2b connected (e.g., electrically connected) to the common voltage line VL2, and the like.

The second insulating layer 150 may be stacked on the second conductive layer 2000.

The first layer 2000a of the second conductive layer 2000 may include a refractory metal to increase the stability of the second conductive layer 2000. The second layer 2000b of the second conductive layer 2000 may include a metal having a low resistivity to prevent a signal delay of the second conductive layer 2000. The second conductive layer 2000 may further include the third layer 2000c and the fourth layer 2000d in addition to the first layer 2000a and the second layer 2000b to decrease a change in taper angle of the side surface of the second conductive layer 2000 and reduce the roughness, thereby preventing disconnection or lifting of an insulating layer (e.g., a second insulating layer 150) formed on the second conductive layer 2000 and preventing a signal line formed on the second insulating layer 150 from being defective.

Referring to FIGS. 17 to 19, the plurality of contact holes LH1 overlapping the first conductive layer 1000 may be formed in the buffer layer 120 and the second insulating layer 150. The contact holes LH2 and LH3 overlapping the second conductive layer 2000 may be formed in the second insulating layer 150.

For example, the third layer 1000c and the fourth layer 1000d of the first conductive layer 1000 may be removed from the portions overlapping the plurality of contact holes LH1 formed in the second insulating layer 150 and the buffer layer 120, e.g., to expose the second layer 1000b of the first conductive layer 1000. The third layer 2000c and the fourth layer 2000d of the second conductive layer 2000 may be removed from the portions overlapping the plurality of contact holes LH2 and LH3 formed in the second insulating layer 150, e.g., to expose the second layer 2000b of the second conductive layer 2000. Thus, the second layer 1000b of the first conductive layer 1000 may be exposed through the plurality of contact holes LH1, and the second layer 2000b of the second conductive layer 2000 may be exposed through the plurality of contact holes LH2 and LH3.

Referring to FIGS. 20 to 22, the third conductive layer 3000 may be disposed on the second insulating layer 150. The third conductive layer 3000 may include the first gate line GL1, the second gate line GL2, the second storage electrode C2 of the storage capacitor C_{ST}, the auxiliary driving voltage line VL1′, the auxiliary common voltage line VL2′, the first-first auxiliary pattern layer AP1a connected (e.g., electrically connected) to the driving voltage line VL1, the second-first auxiliary pattern layer AP2a connected (e.g., electrically connected) to the common voltage line VL2, the third auxiliary pattern layer AP3a connected (e.g., electrically connected) to the initialization voltage line VL3, etc. For example, the third insulating layer 160 and the first organic insulating layer 170 may be formed on the third conductive layer 3000. In FIG. 20, the third conductive layer 3000 is illustrated.

The first layer 3000a of the third conductive layer 3000 including a refractory metal, for example, titanium may be stacked on the second insulating layer 150. The second layer 3000b including a metal having a low resistivity, for example, copper may be stacked on the first layer 3000a. The third layer 3000c including a refractory metal, for example, titanium may be stacked on the second layer 3000b. In another example, the third layer 3000c may not be stacked, but the fourth layer 3000d including transparent conductive oxide (TCO) such as indium tin oxide (ITO), zinc indium tin oxide (ZITO), indium zinc oxide (IZO), and aluminum zinc oxide (AZO) may be stacked on the second layer 3000b.

In case that the third layer 3000c is not stacked on the second layer 3000b, but the fourth layer 3000d is stacked on the second layer 3000b, an upper surface of the second layer 3000b may be in contact with the fourth layer 3000d, and a part of the upper surface of the second layer 3000b in contact with the fourth layer 3000d may be oxidized. Thus, the third layer 3000c including a metal oxide of the third conductive layer 3000 may be formed.

The thickness of the second layer 3000b of the third conductive layer 3000 may be greater than the thickness of the first layer 3000a of the third conductive layer 3000, the thickness of the third layer 3000c of the third conductive layer 3000, and the thickness of the fourth layer 3000d of the third conductive layer 3000. For example, the thickness of the fourth layer 3000d of the third conductive layer 3000 may be about 50 angstroms to about 1000 angstroms.

The third conductive layer 3000 including the first layer 3000a, the second layer 3000b, the third layer 3000c, and the fourth layer 3000d may be stacked and etched on the second insulating layer 150 to form the third conductive layer 3000 including the first gate line GL1, the second gate line GL2, the second storage electrode C2 of the storage capacitor C_{ST}, the auxiliary driving voltage line VL1′, the auxiliary common voltage line VL2′, the first-first auxiliary pattern layer AP1a connected (e.g., electrically connected) to the driving voltage line VL1, the second-first auxiliary pattern layer AP2a connected (e.g., electrically connected) to the common voltage line VL2, the third auxiliary pattern layer AP3a connected (e.g., electrically connected) to the initialization voltage line VL3, and the like.

The first layer 3000a of the third conductive layer 3000 may include a refractory metal to increase the stability of the third conductive layer 3000, and the second layer 3000b of the third conductive layer 3000 may include a metal having a low resistivity to prevent the signal delay of the third conductive layer 3000. The third conductive layer 3000 may further include the third layer 3000c and the fourth layer 3000d in addition to the first layer 3000a and the second layer 3000b to decrease a change in taper angle of the side surface of the third conductive layer 3000 and reduce the roughness, thereby preventing disconnection or lifting of an insulating layer such as the third insulating layer 160 formed on the third conductive layer 3000.

The first gate line GL1 may be connected (e.g., electrically connected) to the gate electrode G2 through a contact hole formed in the second insulating layer 150. The second gate line GL2 may be connected (e.g., electrically connected) to the gate electrode G3 through the contact hole formed in the second insulating layer 150. The second storage electrode C2 may be connected (e.g., electrically connected) to the second region of the semiconductor layer A1 through the contact hole of the second insulating layer 150 and the opening of the first storage electrode C1. The second storage electrode C2 may be connected (e.g., electrically connected) to the light blocking pattern layer LB through the contact holes formed in the second insulating layer 150 and the buffer layer 120. The extension portion of the second storage electrode C2 may be connected (e.g., electrically connected) to the second region of the semiconductor layer A3 through the contact hole formed in the second insulating layer 150. For example, the auxiliary driving voltage line VL1′ may be connected (e.g., electrically connected) to the driving voltage line VL1 through the contact holes formed in the second insulating layer 150 and the buffer layer 120. The auxiliary common voltage line VL2′ may be connected (e.g., electrically connected) to the common voltage line VL2 through the contact holes formed in the second insulating layer 150 and the buffer layer 120. The first-first auxiliary pattern layer AP1a may be connected (e.g., electrically connected) to the first-second auxiliary pattern layer AP1b through the contact hole formed in the second insulating layer 150. The first-first auxiliary pattern layer AP1a may be connected (e.g., electrically connected) to the driving voltage line VL1 through the contact holes formed in the second insulating layer 150 and the buffer layer 120. The first-first auxiliary pattern layer AP1a may be connected (e.g., electrically connected) to the first region of the semiconductor layer A1 through the contact hole formed in the second insulating layer 150. The second-first auxiliary pattern layer AP2a may be connected (e.g., electrically connected) to the common voltage line VL2 through a contact hole LH1 formed in the second insulating layer 150 and the buffer layer 120, and connected (e.g., electrically connected) to the second-second auxiliary pattern layer AP2b through a contact hole LH2 formed in the second insulating layer 150. The second-first auxiliary pattern layer AP2a may be connected (e.g., electrically connected) to the initialization voltage line VL3 through the contact holes formed in the second insulating layer 150 and the buffer layer 120 and may be connected (e.g., electrically connected) to the first region of the semiconductor layer A3 through the contact hole formed in the second insulating layer 150. Furthermore, the connection member CM1 may be connected (e.g., electrically connected) to the data lines DL1, DL2, and DL3 through the contact holes formed in the second insulating layer 150 and the buffer layer 120, and may be connected (e.g., electrically connected) to the first region of the semiconductor layer A2 through the contact hole formed in the second insulating layer 150. The connection member CM2 may be connected (e.g., electrically connected) to the first storage electrode C1 through a contact hole formed in the second insulating layer 150, and may be connected (e.g., electrically connected) to the semiconductor layer A2 through the contact hole formed in the second insulating layer 150.

Referring to FIGS. 23 to 25, the plurality of contact holes H1, H2, and H3 may be formed in the third insulating layer 160 and the first organic insulating layer 170. The fourth conductive layer that may include the pixel electrode E1, the connection electrode CE, etc. of the light emitting diode LED may be formed on the first organic insulating layer 170.

A reflective conductive material, a semi-transmissive conductive material, or a transparent conductive material may be stacked and etched on the first organic insulating layer 170 to form the pixel electrode E1 and the connection electrode CE.

The second organic insulating layer 180 may be formed on the fourth conductive layer, and the emission layer EL may be formed on the fourth conductive layer. For example, the contact hole H3 overlapping the opening OP1 may be formed in the emission layer EL.

The common electrode E2 may be formed on the emission layer EL, and the encapsulation layer 190 may be formed on the common electrode E2 to form the display unit of the display device as illustrated in FIGS. 3 to 7.

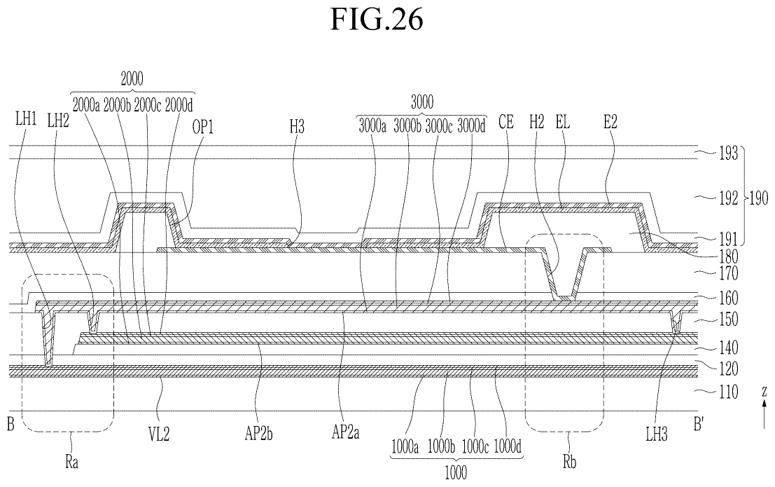

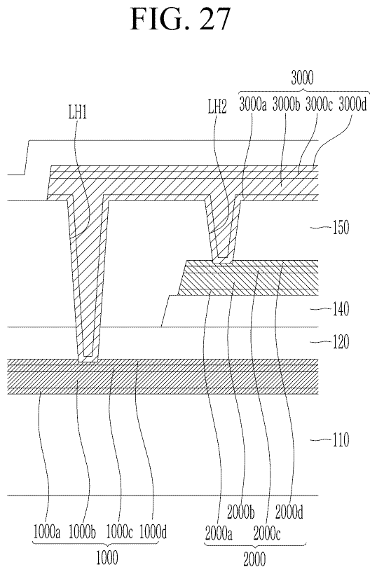

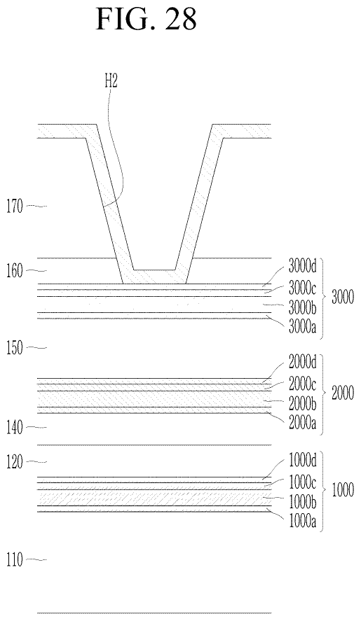

A display device according to an embodiment will be described with reference to FIGS. 26 to 28 along with FIGS. 3 to 7. FIG. 26 is a schematic cross-sectional view of a display device according to an embodiment, and FIGS. 27 and 28 are schematic enlarged views illustrating a part of FIG. 26. FIG. 26 is a schematic cross-sectional view taken along line B-B′ of FIG. 3, and FIGS. 27 and 28 are schematic enlarged views illustrating the first region Ra and the second region Rb of FIG. 26.

Referring to FIGS. 26 to 28 along with FIGS. 3 to 7, the display device of FIGS. 26 to 28 is substantially similar to the display device according to the aforementioned embodiment. A detailed description of the same components will be omitted for descriptive convenience.

For the connection of signal lines disposed on different layers, the plurality of contact holes LH1 overlapping the first conductive layer 1000 may be formed in the second insulating layer 150 and the buffer layer 120. The plurality of contact holes LH2 and LH3 overlapping the second conductive layer 2000 may be formed in the second insulating layer 150. The plurality of contact holes H1 and H2 overlapping the third conductive layer 3000 may be formed in the third insulating layer 160 and the first organic insulating layer 170.

Referring to FIGS. 26 and 27, a part of the fourth layer 1000d of the first conductive layer 1000 may be removed from the portions overlapping the plurality of contact holes LH1 formed in the second insulating layer 150 and the buffer layer 120. Thus, the thickness of the fourth layer 1000d of the first conductive layer 1000 may be small in the portions overlapping the plurality of contact holes LH1 as compared with the fourth layer 1000d of the first conductive layer 1000 in the remaining part which does not overlap the plurality of contact holes LH1 of the first conductive layer 1000. Similarly thereto, a part of the fourth layer 2000d of the second conductive layer 2000 may be removed from the portions overlapping the plurality of contact holes LH2 and LH3 formed in the second insulating layer 150. Thus, the thickness of the fourth layer 2000d of the second conductive layer 2000 may be small in the portions overlapping the plurality of contact holes LH2 and LH3 as compared with the fourth layer 2000d of the second conductive layer 2000 in the remaining part which does not overlap the plurality of contact holes LH2 and LH3 of the second conductive layer 2000.

Referring to FIGS. 26 and 28, similarly to the display device according to the above-described embodiment, the fourth layer 3000d of the third conductive layer 3000 may not be removed from the portions overlapping the plurality of contact holes H1 and H2 formed in the third insulating layer 160 and the first organic insulating layer 170. The fourth layer 3000d of the third conductive layer 3000 is not removed from the portions overlapping the plurality of contact holes H1 and H2. Thus, the contact characteristics of the pixel electrode E1 and the connection electrode CE in contact with the third conductive layer 3000 may be increased.

Many features of the display device according to the embodiment described above with reference to FIGS. 1 to 7 may be all applied to the display device of the FIGS. 26 to 28.

A display device according to an embodiment will be described with reference to FIG. 29. FIG. 29 is a schematic cross-sectional view of a display area in the light emitting diode device according to an embodiment.

Referring to FIG. 29, a display panel 10 may include a display unit 100, a color conversion unit 200, and a filler 400 disposed between the display unit 100 and the color conversion unit 200. The structure of the display unit 100 of the display panel 10 may be similar to the display device according to the above-described embodiment.

The display unit 100 may include a first substrate 110, a transistor TR formed on the first substrate 110, and a light emitting diode LED connected (e.g., electrically connected) to the transistor TR. The transistor TR may include a semiconductor layer AL, a gate electrode GE, a first electrode SE, and a second electrode DE. The first electrode SE may be connected (e.g., electrically connected) to a first region of the semiconductor layer AL and a light blocking pattern layer LB, and the second electrode DE may be connected (e.g., electrically connected) to a second region of the semiconductor layer AL. The illustrated transistor TR may be a first transistor T1. Since the display unit 100 has been described in detail above, the color conversion unit 200 and the filler 400 will be described herein.

The color conversion unit 200 may be disposed on an encapsulation layer 190 of the display unit 100.

The color conversion unit 200 may include a second substrate 210. The second substrate 210 may include an insulating material such as glass or plastic, for example, the first substrate 110 may be a glass substrate.

Color filters 230a, 230b, and 230c may be disposed on the second substrate 210 in a direction toward the display unit 100. In a display area DA, the color filters 230a, 230b, and 230c may overlap openings OP of a second organic insulating layer 180. The color filters 230a, 230b, and 230c include a first color filter 230a that transmits light of a first wavelength and absorbs light of the remaining wavelengths, a second color filter 230b that transmits light of a second wavelength and absorbs light of the remaining wavelengths, and a third color filter 230c that transmits light of a third wavelength and absorbs light of the remaining wavelengths. The first color filter 230a, the second color filter 230b, and the third color filter 230c may overlap a first pixel PX1, a second pixel PX2, and a third pixel PX3, respectively. Accordingly, the light of the first wavelength (corresponding to the first pixel PX1), the light of the second wavelength (corresponding to the second pixel PX2), and the light of the third wavelength (corresponding to the third pixel PX3) emitted to the outside of the display panel 10 may have improved purity. The light of the first wavelength, the light of the second wavelength, and the light of the third wavelength may be red light, green light, and blue light, respectively.

At a boundary area between the pixels PX1, PX2, and PX3, the first color filter 230a, the second color filter 230b, and the third color filter 230c may overlap each other to form a light blocking region. As illustrated in the drawings, the first color filter 230a, the second color filter 230b, and the third color filter 230c may overlap each other to form a light blocking region. In another example, the two color filters may overlap each other to form a light blocking region. For example, the first color filter 230a and the second color filter 230b may overlap each other at a boundary area between the first pixel PX1 and the second pixel PX2, the second color filter 230b and the third color filter 230c may overlap each other at a boundary area between the second pixel PX2 and the third pixel PX3, and the third color filter 230c and the first color filter 230a may overlap each other at a boundary area between the third pixel PX3 and the first pixel PX1. In a non-display area NA, the first color filter 230a, the second color filter 230b, and the third color filter 230c may overlap each other to form a light blocking region. The third color filter 230c, the first color filter 230a, and the second color filter 230b may be stacked on the second substrate 210 in sequence. In another example, the third color filter 230c, the first color filter 230a, and the second color filter 230b may be stacked in another order. The light blocking region may be provided by forming a light blocking member instead of overlapping of the color filters 230a, 230b, and 230c.

A low refractive index layer 240 may be disposed on the color filters 230a, 230b, and 230c. The low refractive index layer 240 may be disposed to cover the entire second substrate 210. The low refractive index layer 240 may include an organic material or an inorganic material having a low refractive index. The refractive index of the low refractive index layer 240 may be about 1.1 to about 1.3. The low refractive index layer 240 may be disposed at a position different from the position illustrated. For example, the low refractive index layer 240 may be disposed among the color conversion layers 270a and 270b, a transmission layer 270c and a second capping layer 280. The color conversion unit 200 may include low refractive index layers. For example, the color conversion unit 200 may further include a low refractive index layer disposed among the color conversion layers 270a and 270b, the transmission layer 270c and the second capping layer 280 in addition to the low refractive index layer 240 disposed between the color filters 230a, 230b, and 230c and a first capping layer 250 as illustrated in the drawing.

The first capping layer 250 may be disposed on the low refractive index layer 240. The first capping layer 250 may be disposed to cover (e.g., entirely cover) the low refractive index layer 240 and protect the low refractive index layer 240. The first capping layer 250 may include an inorganic insulating material such as silicon oxide, silicon nitride, or silicon oxynitride, and may be a single layer or multi-layer.

A bank 260 may be disposed on the first capping layer 250. The bank 260 may be disposed in the display area DA and overlap the second organic insulating layer 180. The bank 260 may overlap the light blocking region where the first color filter 230a, the second color filter 230b, and the third color filter 230c overlap each other. The bank 260 may be disposed at a boundary area between the pixels PX1, PX2, and PX3. The bank 260 may partition a pixel region. The bank 260 may include an organic insulating material such as an acrylic polymer, an imide-based polymer, or an amide-based polymer. The bank 260 may be a black bank including a colored pigment, such as a black pigment. In another example, the bank 260 may be transparent.

The first color conversion layer 270a, the second color conversion layer 270b, and the transmission layer 270c may be disposed on the first capping layer 250. The first color conversion layer 270a, the second color conversion layer 270b, and the transmission layer 270c may be disposed in a space (i.e., an opening of the bank 260) defined by the bank 260. The first color conversion layer 270a, the second color conversion layer 270b, and the transmission layer 270c may be partitioned or separated by the bank 260. The first color conversion layer 270a, the second color conversion layer 270b, and the transmission layer 270c may be formed by an inkjet printing process.

The first color conversion layer 270a may overlap the first color filter 230a. The first color conversion layer 270a may overlap the light emitting diode LED corresponding to the first pixel PX1, and may convert light incident from the light emitting diode LED to light of a first wavelength. The light of the first wavelength may be red light having a maximum emission peak wavelength of about 600 nm to about 650 nm, for example, about 620 nm to about 650 nm.

The second color conversion layer 270b may overlap the second color filter 230b. The second color conversion layer 270b may overlap the light emitting diode LED corresponding to the second pixel PX2 and may convert light incident from the light emitting diode LED to light of a second wavelength. The light of the second wavelength may be green light having a maximum emission peak wavelength of about 500 nm to about 550 nm, for example, about 510 nm to about 550 nm.

The transmission layer 270c may overlap the third color filter 230c. The transmission layer 270c may overlap the light emitting diode LED corresponding to the third pixel PX3 and transmit light incident from the light emitting diode LED. The light passing through the transmission layer 270c may be light of a third wavelength. The light of the third wavelength may be blue light having a maximum emission peak wavelength of about 380 nm to about 480 nm, for example, about 420 nm or more, about 430 nm or more, about 440 nm or more, or about 445 nm or more, and about 470 nm or less, about 460 nm or less, or about 455 nm or less.

The first color conversion layer 270a and the second color conversion layer 270b may include first quantum dots and second quantum dots, respectively. For example, light incident to the first color conversion layer 270a may be converted and emitted into light of a first wavelength by the first quantum dots. Light incident to the second color conversion layer 270b may be converted and emitted into light of a second wavelength by the second quantum dots. The first color conversion layer 270a, the second color conversion layer 270b, and the transmission layer 270c may include scatterers. The scatterers may scatter light incident to the first color conversion layer 270a, the second color conversion layer 270b, and the transmission layer 270c to improve light efficiency.

The first quantum dots and the second quantum dots (hereinafter, also referred to as semiconductor nanocrystals) may include each independently II-VI compounds, III-V compounds, IV-VI compounds, IV elements or compounds, I-III-VI compounds, II-III-VI compounds, I-II-IV-VI compounds, or combinations thereof.

The II-VI compounds may be selected from the group consisting of binary compounds selected from the group consisting of CdSe, CdTe, ZnS, ZnSe, ZnTe, ZnO, HgS, HgSe, HgTe, MgSe, MgS and a mixture thereof; ternary compounds selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof. The II-VI compounds may further include III metals.

The III-V compounds may be selected from the group consisting of binary compounds selected from the group consisting of GaN, GaP, GaAs, GaSb, AN, AlP, AlAs, AlSb, InN, InP, InAs, InSb and a mixture thereof; ternary compounds selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb and a mixture thereof; and quaternary compounds selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The III-V compounds may further include II metals (e.g., InZnP).

The IV-VI compounds may be selected from the group consisting of binary compounds selected from the group consisting of SnS, SnSe, SnTe, PbS, PbSe, PbTe and a mixture thereof; ternary compounds selected from the group consisting of SnSeS, SnSeTe, SnSTe, PbSeS, PbSeTe, PbSTe, SnPbS, SnPbSe, SnPbTe and a mixture thereof; and quaternary compounds selected from the group consisting of SnPbSSe, SnPbSeTe, SnPbSTe and a mixture thereof.

The IV elements or compounds may be selected from the group consisting of elementary compounds selected from the group consisting of Si, Ge, and a combination thereof; and binary compounds selected from the group consisting of SiC, SiGe and a combination thereof.

The I-III-VI compounds may be selected from CuInSe₂, CuInS₂, CuInGaSe and CuInGaS.

The II-III-VI compounds may be selected from the group consisting of ZnGaS, ZnAlS, ZnInS, ZnGaSe, ZnAlSe, ZnlnSe, ZnGaTe, ZnAlTe, ZnInTe, ZnGaO, ZnAlO, ZnInO, HgGaS, HgAlS, HgInS, HgGaSe, HgAlSe, HglnSe, HgGaTe, HgAlTe, HglnTe, MgGaS, MgAlS, MgInS, MgGaSe, MgAlSe, MglnSe and combinations thereof.

The I-II-IV-VI compounds may be selected from CuZnSnSe and CuZnSnS.

The quantum dots may not include cadmium. The quantum dots may include semiconductor nanocrystals based on the III-V compounds including indium and phosphorus. The III-V compounds may further include zinc. The quantum dots may include semiconductor nanocrystals based on the II-VI compounds including a chalcogen element (e.g., sulfur, selenium, tellurium, or combinations thereof) and zinc.

In the quantum dots, the above-mentioned binary compounds, ternary element compounds, and/or quaternary compounds may be included in particles at a uniform concentration, or may be present in the same particles in which the concentration distribution is partially divided into different states. For example, the quantum dots may have a core/shell structure in which one quantum dot surrounds other quantum dots. An interface between the core and the shell may have a concentration gradient in which the concentration of the elements included in the shell decreases toward the center.

In some embodiments, quantum dots may have a core-shell structure including a core including the aforementioned nanocrystals and a shell surrounding the core. The shell of the quantum dot may function as a protective layer for maintaining semiconductor properties and/or as a charging layer for imparting electrophoretic properties to the quantum dot by preventing chemical modification of the core. The shell may be a single-layer or a multi-layer. The interface between the core and the shell may have a concentration gradient in which the concentration of the elements included in the shell decreases toward the center. Examples of the shell of the quantum dot may include a metal or non-metal oxide, a semiconductor compound, or a combination thereof.

The metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like, or a ternary compound such as MgAl₂O₄, CoFe₂O₄, NiFe₂O₄, CoMn₂O₄, and the like.

The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like.

The quantum dots may have a full width of half maximum of the emission wavelength spectrum of about 45 nm or less, about 40 nm or less, or about 30 nm or less, and color purity or color reproducibility may be improved in this range. Since light emitted through the quantum dots is emitted in all directions, a viewing angle may be improved.

In the quantum dot, a shell material and a core material may have different energy bandgaps. For example, the energy bandgap of the shell material may be greater or smaller than that of the core material. The quantum dot may have a multi-layered shell. In the multi-layered shell, the energy bandgap of an outer layer may be greater than the energy bandgap of an inner layer (i.e., a layer closer to the core). In the multi-layered shell, the energy bandgap of the outer layer may be smaller than the energy bandgap of the inner layer.

For example, the shape of the quantum dot may include a sphere, a polyhedron, a pyramid, a multipod, a square, a cuboid, a nanotube, a nanorod, a nanowire, a nanosheet, or a combination thereof. However, embodiments are not limited thereto.

The quantum dot may include an organic ligand (e.g., with a hydrophobic and/or hydrophilic moiety). The organic ligand moiety may be bound to the surface of the quantum dot. The organic ligand may include RCOOH, RNH₂, R₂NH, R₃N, RSH, R₃PO, R₃P, ROH, RCOOR, RPO (OH)₂, RHPOOH, R₂HPOOH, or a combination thereof. Here, R may be each independently a C₃ to C₄₀ substituted or unsubstituted aliphatic hydrocarbon group such as C₃ to C₄₀ (e.g., C₅ or more and C₂₄ or less) substituted or unsubstituted alkyl and substituted or unsubstituted alkenyl, a C₆ to C₄₀ (e.g., C₆ or more and C₂₀ or less) substituted or unsubstituted aromatic hydrocarbon group such as a substituted or unsubstituted C₆ to C₄₀ aryl group, or a combination thereof.

Examples of the organic ligand may include thiol compounds such as methane thiol, ethane thiol, propane thiol, butane thiol, pentane thiol, hexane thiol, octane thiol, dodecane thiol, hexadecane thiol, octadecane thiol, benzyl thiol, and the like; amines such as methanamine, ethanamine, propanamine, butanamine, pentylamine, hexylamine, octylamine, nonylamine, decylamine, dodecylamine, hexadecylamine, octadecylamine, dimethylamine, diethylamine, dipropylamine, tributyl amine, trioctyl amine, and the like; carboxylic acid compounds such as methanic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, and the like; phosphine compounds such as methyl phosphine, ethyl phosphine, propyl phosphine, butyl phosphine, pentyl phosphine, octyl phosphine, dioctyl phosphine, tributyl phosphine, trioctyl phosphine, and the like; phosphine compounds or oxide compounds thereof such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, and the like; C₅ to C₂₀ alkyl phosphinic acids such as hexylphosphinic acid, octylphosphinic acid, dodecanephosphinic acid, tetradecanephosphinic acid, hexadecanephosphinic acid, octadecanephosphinic acid, and the like; C₅ to C₂₀ alkyl phosphonic acids; and the like. The quantum dot may include a hydrophobic organic ligand alone or in a mixture of one or more thereof. The hydrophobic organic ligand may not include a photopolymerizable moiety (e.g., an acrylate group, a methacrylate group, etc.).

The second capping layer 280 may be disposed on the bank 260. The second capping layer 280 may be disposed to cover (e.g., entirely cover) the second substrate 210. The second capping layer 280 may cover the first color conversion layer 270a, the second color conversion layer 270b, and the transmission layer 270c. The second capping layer 280 may include an inorganic insulating material such as silicon oxide, silicon nitride, or silicon oxynitride, and may be a single layer or a multi-layer.

The low refractive index layer 240, the first capping layer 250, and the second capping layer 280 may cover side surfaces of the color filters 230a, 230b, and 230c at the edge portion of the color conversion unit 200. The low refractive index layer 240, the first capping layer 250, and the second capping layer 280 may be formed up to the edge portion of the second substrate 210, and the low refractive index layer 240 may be in contact with the second substrate 210 at the edge portion of the color conversion unit 200. The low refractive index layer 240, the first capping layer 250, and the second capping layer 280 may form a blocking member that prevents moisture, oxygen, etc. from penetrating from the edge portion of the color conversion unit 200.

The filler 400 may be disposed between the color conversion unit 200 and the display unit 100. The filler 400 may fill a space between the display unit 100 and the color conversion unit 200 to increase compressing resistance between the display unit 100 and the color conversion unit 200. A surface of the filler 400 may be in contact with the second capping layer 280, and another surface of the filler 400 may be in contact with the encapsulation layer 190. The filler 400 may be formed by applying a filling material on the second capping layer 280, overlapping the display unit 100, and then curing the display unit 100. The filler 400 may include an organic material such as an epoxy resin.

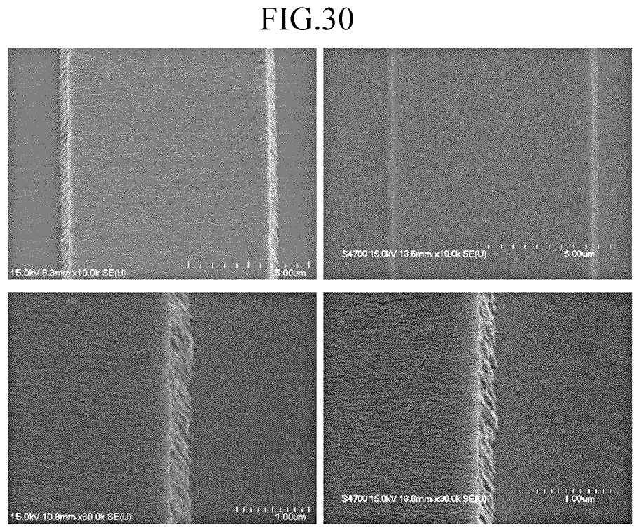

Results of Experimental Example will be described with reference to FIGS. 30 to 32. FIGS. 30, 31 and 32 are electron micrographs showing results of Experimental Example.

In Experimental Example, with respect to a first case of forming a metal layer in a double-layer structure to include a first layer made of titanium and a second layer made of copper, a second case of forming a metal layer in a triple-layer structure to include a first layer made of titanium, a second layer made of copper, and a third layer made of indium tin oxide, and a third case of forming a metal layer in a quadruple-layer structure to include a first layer made of titanium, a second layer made of copper, a third layer made of titanium, and a fourth layer made of indium tin oxide, the surfaces of the metal layers are measured by electron micrographs at magnifications of 10 K and 30 K, and the results are shown in FIGS. 30 to 33. Except for the layer structures of the metal layers, other conditions are substantially the same.

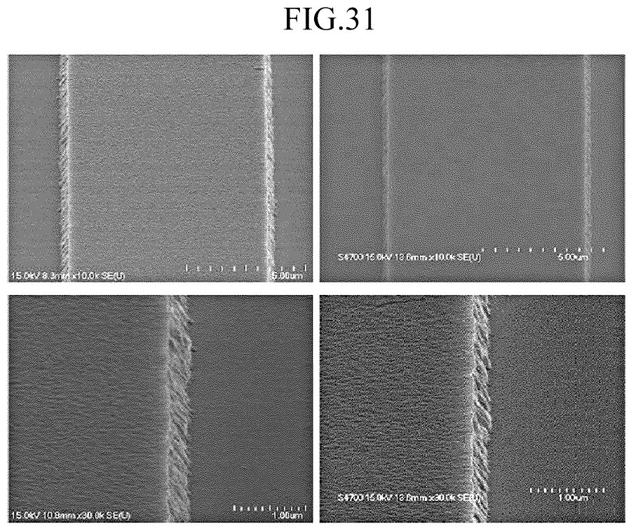

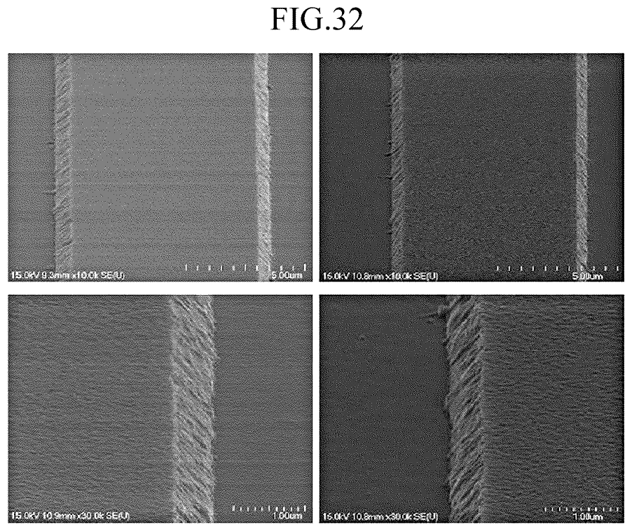

The result of the first case is shown in FIG. 30, the result of the second case is shown in FIG. 31, and the result of the third case is shown in FIG. 32. In FIGS. 30 to 32, photographs measured at the magnification of 10 K are shown at the top, and photographs measured at the magnification of 30 K are shown at the bottom.

Referring to FIGS. 30 to 32, as compared to the first case of forming the metal layer in the double-layer structure, similarly to the display devices according to the embodiments, in the second case of forming the metal layer in the triple-layer structure to include the first layer made of titanium, the second layer made of copper, and the third layer made of indium tin oxide, and the third case of forming the metal layer in the quadruple-layer structure to include the first layer made of titanium, the second layer made of copper, the third layer made of titanium, and the fourth layer made of indium tin oxide, the surface roughness of the side of the metal layer may be reduced.

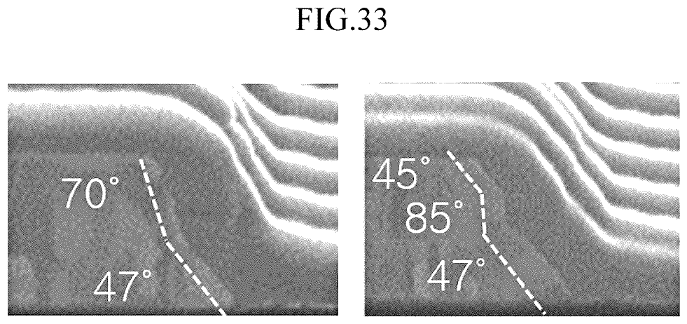

Another Experimental Example will be described with reference to FIG. 33. FIG. 33 is an electron micrograph showing the results of another Experimental Example.

In Experimental Example, with respect to a fourth case of forming a metal layer in a double-layer structure and a fifth case of forming a metal layer in a triple-layer structure, cross sections of the metal layers are measured by an electron microscope, and the results are shown in FIG. 33. Except for the layer structures of the metal layers, other conditions are substantially the same.

In FIG. 33, the result of the fourth case is shown on the left and the result of the fifth case is shown on the right.

Referring to FIG. 33, as compared with the fourth case of forming the metal layer in the double-layer structure, according to the fifth case of forming the metal layer in the triple-layer structure, a change in a side taper angle of the metal layer may be gentle, and the taper angle of an upper layer made of indium tin oxide may be the gentlest.

As such, similarly to the display devices according to the embodiments, in case that the upper layer of the metal layer is formed of indium tin oxide, the change in the side taper angle of the metal layer may be gentle.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
an emission layer disposed on the substrate; and
a plurality of signal lines disposed on the substrate and electrically connected to the emission layer, the plurality of signal lines including a first signal line, wherein
the first signal line includes:
a first layer including a refractory metal;
a second layer disposed on the first layer and including a low-resistance metal;
a third layer disposed on the second layer and including a first metal oxide; and
a fourth layer disposed on the third layer and including a second metal oxide,
and
the first metal oxide of the third layer includes the low-resistance metal of the second layer.

2. The display device of claim 1, wherein:
the first layer includes titanium,
the second layer includes copper, and
the third layer includes copper oxide.

3. The display device of claim 2, wherein:
the fourth layer includes transparent conductive oxide (TCO).

4. The display device of claim 3, wherein:
the fourth layer includes at least one of indium tin oxide (ITO), zinc indium tin oxide (ZITO), indium zinc oxide (IZO), and aluminum zinc oxide (AZO).

5. The display device of claim 4, wherein:
a thickness of the fourth layer is about 50 angstroms to about 1000 angstroms.

6. The display device of claim 5, wherein:
a thickness of the second layer is greater than a thickness of the first layer and a thickness of the third layer.

7. The display device of claim 6, wherein:
the third layer and the fourth layer of the first signal line are removed from a first portion of the first signal line to expose the second layer of the first signal line.

8. The display device of claim 7, further comprising:
a first insulating layer disposed on the first signal line and including a contact hole,
wherein the first portion of the first signal line overlaps the contact hole.

9. The display device of claim 6, wherein:
a part of the fourth layer of the first signal line is removed from a first portion of the first signal line.

10. The display device of claim 9, further comprising:
a first insulating layer disposed on the first signal line and including a contact hole,
wherein the first portion of the first signal line overlaps the contact hole.

11. The display device of claim 1, further comprising:
a transistor electrically connected to the emission layer and including a semiconductor layer,
wherein the first signal line is disposed between the substrate and the semiconductor layer.

12. The display device of claim 11, wherein:
the third layer and the fourth layer of the first signal line are removed from a first portion of the first signal line to expose the second layer of the first signal line.

13. The display device of claim 12, further comprising:
a first insulating layer disposed on the first signal line and including a contact hole,
wherein the first portion of the first signal line overlaps the contact hole.

14. The display device of claim 11, wherein:
a part of the fourth layer of the first signal line is removed from a first portion of the first signal line.

15. The display device of claim 14, further comprising:
a first insulating layer disposed on the first signal line and including a contact hole,
wherein the first portion of the first signal line overlaps the contact hole.

16. A display device comprising:
a substrate;
a first conductive layer disposed on the substrate;
a first insulating layer disposed on the first conductive layer;
a semiconductor layer disposed on the first insulating layer;
a second insulating layer disposed on the semiconductor layer;
a second conductive layer disposed on the second insulating layer;
a third insulating layer disposed on the second conductive layer;
a third conductive layer disposed on the third insulating layer;
a fourth insulating layer disposed on the third conductive layer; and
an emission layer disposed on the fourth insulating layer and electrically connected to the third conductive layer, wherein
each of the first conductive layer and the second conductive layer includes:
a first layer including a refractory metal;
a second layer disposed on the first layer and including a low-resistance metal;
a third layer disposed on the second layer and including a first metal oxide;
and
a fourth layer disposed on the third layer and including a second metal oxide,
the third layer and the fourth layer of the first conductive layer are removed from a first portion of the first conductive layer, and
the third layer and the fourth layer of the second conductive layer are removed from a second portion of the second conductive layer.

17. The display device of claim 16, wherein:
the first insulating layer, the second insulating layer and the third insulating layer include a first contact hole overlapping the first portion of the first conductive layer,
the third insulating layer includes a second contact hole overlapping the second portion of the second conductive layer, and
the third conductive layer is electrically connected to the first conductive layer and the second conductive layer through the first contact hole and the second contact hole.

18. The display device of claim 17, wherein:
the first layer includes titanium,
the second layer includes copper,
the third layer includes copper oxide, and
the fourth layer includes transparent conductive oxide (TCO).

19. The display device of claim 18, wherein:
the third conductive layer includes:
a first layer including a refractory metal;
a second layer disposed on the first layer and including a low-resistance metal;
a third layer disposed on the second layer and including a refractory metal; and
a fourth layer disposed on the third layer and including a second metal oxide,
the fourth insulating layer includes a third contact hole overlapping a third portion of the third conductive layer,
the emission layer is electrically connected to the third conductive layer through the third contact hole, and
the fourth layer is not removed from the third portion of the third conductive layer.

20. The display device of claim 17, wherein:
the first layer of the third conductive layer includes titanium,
the second layer of the third conductive layer includes copper,
the third layer of the third conductive layer includes titanium, and
the fourth layer of the third conductive layer includes transparent conductive oxide (TCO).
